(19) United States
(12) Patent Application Publication
(10) Pub. No.: US 2026/0198049 A1
(43) Pub. Date: Jul. 9, 2026

(54) NANOSTRUCTURE FIELD-EFFECT TRANSISTOR DEVICES AND METHODS OF FORMING

(71) Applicant: Taiwan Semiconductor Manufacturing co., Ltd., Hsinchu (TW)

(72) Inventors: Yen Chuang, Baoshan Township (TW); Chun Wei Chen, Hsinchu (TW); Yu-Hsing Lin, Tainan City (TW); Chien-Chia Cheng, Hsinchu (TW)

(21) Appl. No.: 19/217,246

(22) Filed: May 23, 2025

Related U.S. Application Data
(60) Provisional application No. 63/743,394, filed on Jan. 9, 2025.

(51) Int. Cl. H10D 62/00; H10D 30/00; H10D 30/01; H10D 62/13; H10D 64/01; H10D 64/62

(52) U.S. Cl. CPC H10D 62/021; H10D 30/0193; H10D 30/503; H10D 30/508; H10D 62/151; H10D 64/01; H10D 64/62

(57) ABSTRACT

A method includes forming a fin structure that protrudes above a substrate; forming a source/drain opening in the fin structure adjacent to the gate structure; and forming a source/drain region in the source/drain opening. Forming the source/drain region comprises forming a first doped epitaxial material in the source/drain opening, wherein the first doped epitaxial material comprises a first semiconductor material doped with a first dopant; after forming the first doped epitaxial material, removing a portion of the first doped epitaxial material to form a cavity in the first doped epitaxial material; and forming a second doped epitaxial material in the cavity, wherein the second doped epitaxial material comprises the first semiconductor material doped with the first dopant, wherein a second concentration of the first dopant in the second doped epitaxial material is higher than a first concentration of the first dopant in the first doped epitaxial material.

### PRIORITY CLAIM AND CROSS-REFERENCE

This application claims priority to U.S. Provisional Application No. 63/743,394, filed Jan. 9, 2025 and entitled “Shape of Contact EPI,” which application is incorporated herein by reference.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A, 5B, 5C, 6A, 6B, 6C, 7A, 7B, 7C, 8A, 8B, 8C, 9A, 9B, 9C, 10A, 10B, 10C, 11A, 11B, 11C, 12, 13, 14A, 14B, 14C, 15A, 15B, 16A, 16B, 17A, 17B, and 18 are cross-sectional views of a portion of a nanostructure field-effect transistor (NSFET) device at various stages of manufacturing, in accordance with an embodiment.

FIGS. 19A and 19B illustrate examples dopant concentrations in the source/drain regions of an NSFET device, in some embodiments.

FIG. 20 illustrates a cross-sectional view of a portion of an NSFET device at a certain stage of manufacturing, in accordance with an embodiment.

FIG. 21 illustrates a cross-sectional view of a portion of an NSFET device at a certain stage of manufacturing, in accordance with an embodiment.

FIGS. 22 and 23 illustrate cross-sectional views of a portion of an NSFET device at certain stages of manufacturing, in accordance with an embodiment.

FIGS. 24 and 25 illustrate cross-sectional views of a portion of an NSFET device at certain stages of manufacturing, in accordance with an embodiment.

FIGS. 26 and 27 illustrate cross-sectional views of a portion of an NSFET device at certain stages of manufacturing, in accordance with an embodiment.

FIG. 28 illustrates a cross-sectional view of a portion of an NSFET device at a certain stage of manufacturing, in accordance with an embodiment.

FIG. 29 illustrates a cross-sectional view of a portion of an NSFET device at a certain stage of manufacturing, in accordance with an embodiment.

FIG. 30 illustrates a cross-sectional view of a portion of an NSFET device at a certain stage of manufacturing, in accordance with an embodiment. FIGS. 31A and 31B together illustrate a flow chart of a method of forming a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

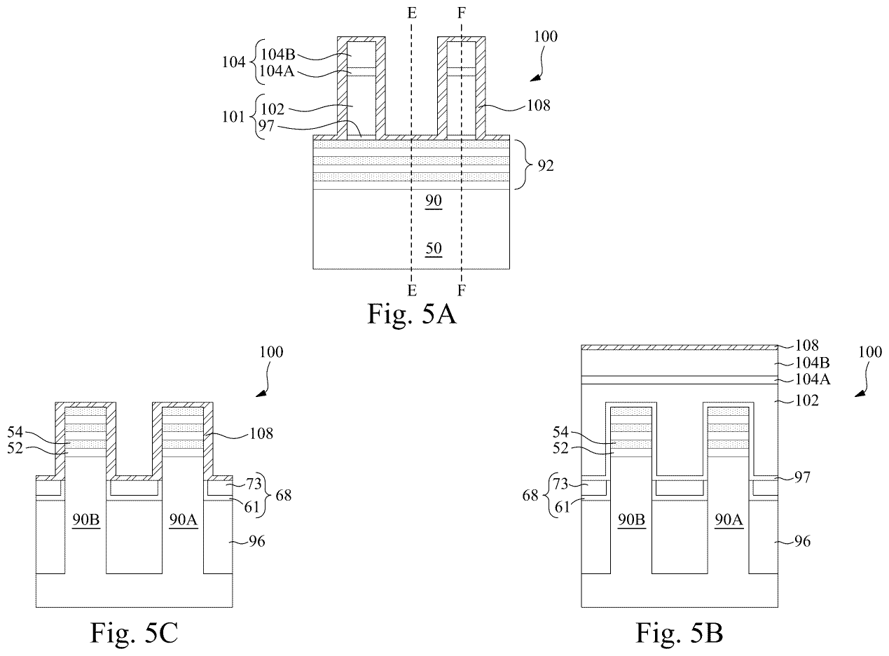

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise specified, the same or similar reference numeral in different figures refer to the same or similar component formed by a same or similar formation process using a same or similar material(s). In addition, figures with the same reference numeral but different alphabets (e.g., FIGS. 5A-5C) illustrate different views of the device at the same stage of processing.

In some embodiments, during the formation process for a source/drain contact of an n-type device, the top portion of a first doped epitaxial material of a source/drain region is replaced with a second doped epitaxial material. The first doped epitaxial material and the second doped epitaxial material comprise a same semiconductor material and a same n-type dopant, but the second doped epitaxial material has a higher concentration of the n-type dopant than the first doped epitaxial material. A silicide region is formed on the second doped epitaxial material, and the source/drain contact is formed on the silicide region. The higher dopant concentration in the second doped epitaxial material results in lower Schottky barrier height and higher carrier tunneling probability, which advantageously reduce the electrical resistance of the source/drain contact formed.

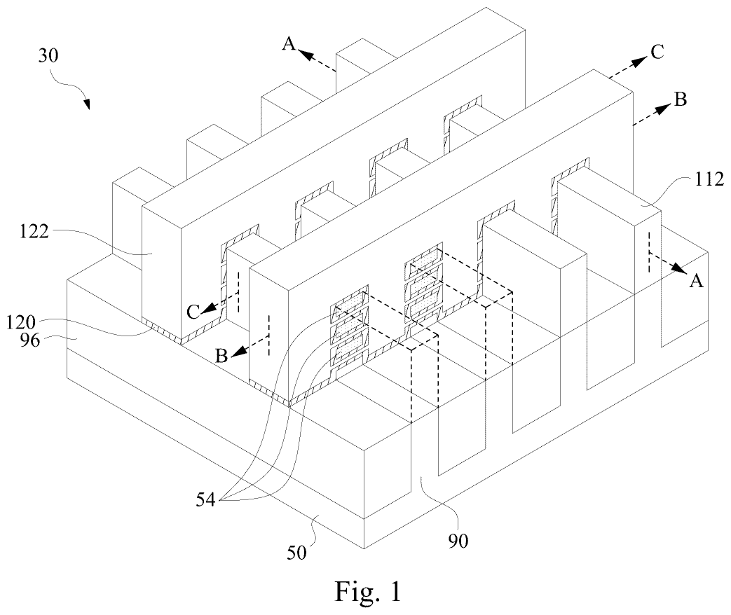

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between the source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the fin 90 and in a direction of, for example, a current flow between the source/drain regions 112 of the NSFET device. Cross-section B-B is perpendicular to cross-section A-A, and is along a longitudinal axis of the gate electrode 122 and in a direction, for example, perpendicular to the direction of current flow between the source/drain regions 112 of the NSFET device 30. Cross-section C-C is parallel to cross-section B-B and extends through source/drain regions 112 of the NSFET device. Subsequent figures may refer to these reference cross-sections for clarity.

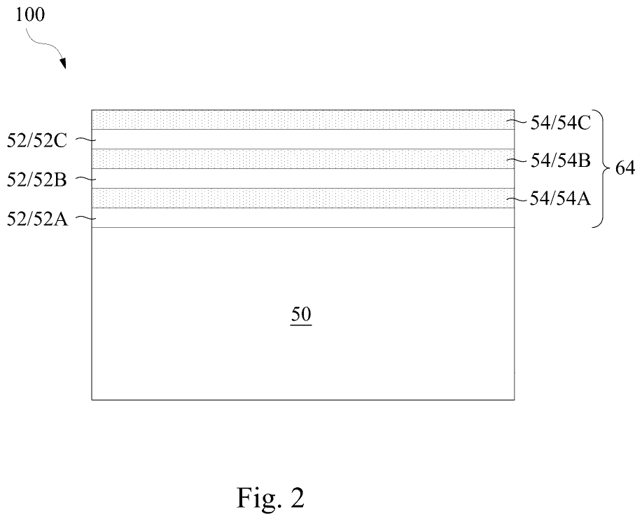

FIGS. 2, 3A, 3B, 4A, 4B, 5A, 5B, 5C, 6A, 6B, 6C, 7A, 7B, 7C, 8A, 8B, 8C, 9A, 9B, 9C, 10A, 10B, 10C, 11A, 11B, 11C, 12, 13, 14A, 14B, 14C, 15A, 15B, 16A, 16B, 17A, 17B, and 18 are cross-sectional views of a portion of a nanostructure field-effect transistor (NSFET) device 100 at various stages of manufacturing, in accordance with an embodiment.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the semiconductor materials illustrated in FIG. 2 are merely non-limiting examples. Other numbers of layers are also possible and are fully intended to be included within the scope of the present disclosure.

In some embodiments, the first semiconductor material 52 is a first type of epitaxial material, such as silicon germanium (SiₓGe₁₋ₓ, where x can be in the range of 0 to 1), and the second semiconductor material 54 is a second type of epitaxial material, such as silicon. The multi-layer stack 64 (which may also be referred to as an epitaxial material stack) will be patterned to form channel regions of an NSFET in subsequent processing. In particular, the multi-layer stack 64 will be patterned and etched to form nanostructures (e.g., nanosheets or nanowires), with the channel regions of the resulting NSFET including multiple horizontally extending nanostructures.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed.

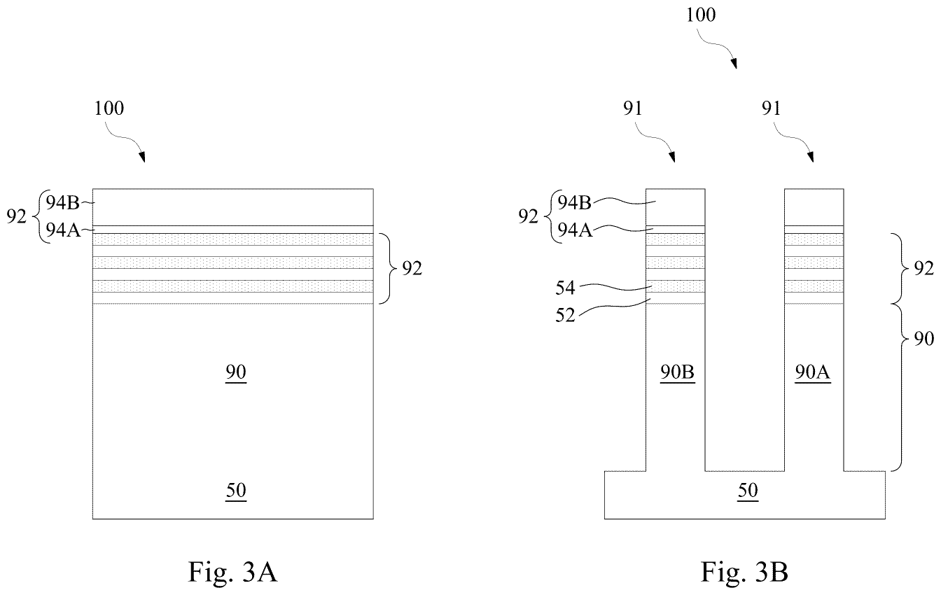

FIGS. 3A, 3B, 4A, 4B, 5A, 5B, 5C, 6A, 6B, 6C, 7A, 7B, 7C, 8A, 8B, 8C, 9A, 9B, 9C, 10A, 10B, 10C, 11A, 11B, 11C, 12, 13, 14A, 14B, 14C, 15A, 15B, 16A, 16B, 17A, 17B, and 18 are cross-sectional views of the NSFET device 100 at subsequent stages of manufacturing, in accordance with an embodiment. FIGS. 3A, 4A, 5A, 6A, 7A, 8A, 9A, 10A, 11A, 12, 13, 14A, 15A, 16A, 17A, and 18 are cross-sectional views along cross-section A-A in FIG. 1. FIGS. 3B, 4B, 5B, 6B, 7B, 8B, 9B, 10B, 11B, 14B, 15B, 16B, and 17B are cross-sectional views along cross-section B-B in FIG. 1. FIGS. 5C, 6C, 7C, 8C, 9C, 10C, 11C, and 14C are cross-sectional views along cross-section C-C in FIG. 1. The number of fins and the number of gate structures illustrated in the figures are merely non-limiting examples, it should be appreciated that other numbers of fins and other numbers of gate structures may also be formed.

In FIGS. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etching process, such as a reactive ion etch (RIE), neutral beam etch (NBE), the like, or a combination thereof. The etching is an anisotropic etching process, in some embodiments. After the etching process, the patterned multi-layer stack 64 forms the layer stack 92, and the patterned portion of the substrate 50 forms the fin 90 (e.g., 90A or 90B), as illustrated in FIGS. 3A and 3B. The remaining (e.g., un-patterned) portion of the substrate 50 is referred to as the substrate 50 in FIGS. 3A and 3B and subsequent figures. Therefore, in the illustrated embodiment, the layer stack 92 also includes alternating layers of the first semiconductor material 52 and the second semiconductor material 54. The fin 90 is formed of a same material as the substrate 50. In the example of FIGS. 3A and 3B, fins 90A and 90B are formed to extend parallel to each other.

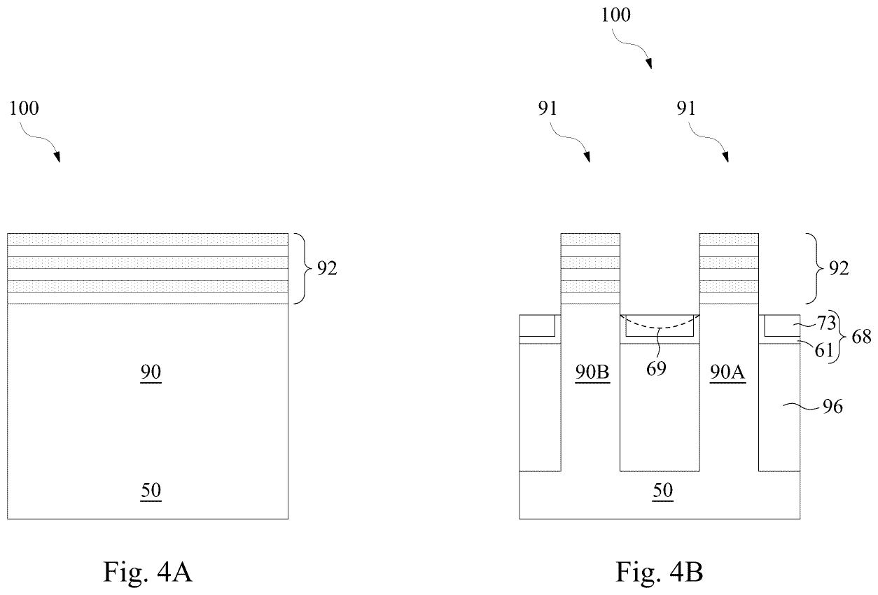

Next, in FIGS. 4A and 4B, shallow trench isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed. In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material disposed over the fin structures 91. In some embodiments, a planarization process such as a chemical mechanical polish (CMP), an etch back process, combinations thereof, or the like, may be utilized. The planarization process exposes the layer stacks 92 such that top surfaces of the layer stacks 92 and the insulation material are level after the planarization process is complete. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than the material of the fin 90 and the layer stack 92). For example, a chemical oxide removal with a suitable etchant such as dilute hydrofluoric (dHF) acid may be used.

Still referring to FIGS. 4A and 4B, an STI protection structure 68 is formed on the upper surfaces of the STI regions 96. The STI protection structure 68 may include a liner layer 61 and a hard mask layer 73. The STI protection structure 68 protects portions of the STI regions 63 disposed directly under the subsequently formed dummy gate structure during a subsequent sheet formation process (e.g., an etching process). Details are discussed hereinafter.

In some embodiment, the liner layer 61 is formed over the layer stacks 92 and over the STI regions 96. The liner layer 61 may be a suitable dielectric material such as silicon oxide, and may be formed using a suitable deposition method such as CVD, atomic layer deposition (ALD), or the like. Besides silicon oxide, other suitable material, such as a dielectric material that provides high etching selectivity from the layer stack 92 and the subsequently formed hard mask layer 73 may also be used.

Next, the hard mask layer 73 is formed over the liner layer 61. The hard mask layer 73 is formed of a material different from the liner layer 61 and the STI regions 96. In some embodiments, the material of the hard mask layer 73 is chosen to provide high etching selectivity from the material of the STI regions 96. In an embodiment, the STI regions 96 is formed of silicon oxide, and the hard mask layer 73 is formed of silicon nitride. Besides silicon nitride, other suitable materials, such as silicon oxynitride, silicon oxycarbonitride, or the like, may also be used to form the hard mask layer 73. A suitable formation method, such as CVD, plasm-enhanced CVD (PECVD), or the like, may be used to form the hard mask layer 73.

Next, a plurality of etching processes, which may include dry etching, wet etching, combinations thereof, or the like, are performed to remove portions of the liner layer 61 and the hard mask layer 73 from the upper surfaces and the sidewalls of the layer stacks 92. The remaining portions of the liner layer 61 and the hard mask layer 73 on the upper surfaces of the STI regions 96 form the STI protection structure 68.

In the example of FIG. 4B, the liner layer 61 of the STI protection structure 68 extends along the sidewalls and the bottom surface of the hard mask layer 73 of the STI protection structure 68. In some embodiments, the upper surface of the STI protection structure 68 is a flat surface, as illustrated in FIG. 4B. In some embodiments, the upper surface of the STI protection structure 68 between adjacent fin structures 91 is a concave surface, as illustrated by the dashed line 69 in FIG. 4B. Subsequent drawings use the example where the STI protections structure 68 has a flat upper surface, with the understanding that the upper surface of the STI protection structure 68 may have other shapes, such as a concave shape, or a convex shape. These and other variations are fully intended to be included within the scope of the present disclosure.

Next, in FIGS. 5A-5C, a dummy dielectric layer 97 is formed over the STI protection structure 68 and along the sidewalls and the top surfaces of the fin structure 91. The dummy dielectric layer 97 may be, for example, silicon oxide, silicon nitride, a combination thereof, or the like, and may be deposited or thermally grown according to acceptable techniques.

Next, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by a CMP. The dummy gate layer may be selected from a group including amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other suitable techniques.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectric 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. Each dummy gate 102 and the underlying dummy gate dielectric 97 are collectively referred to as a dummy gate structure 101.

Next, a gate spacer layer 108 is formed by conformally depositing an insulating material over the layer stacks 92, the STI protection structure 68, and the dummy gate structures 101. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

FIGS. 5B and 5C illustrate cross-sectional views of the NSFET device 100 in FIG. 5A along cross-sections F-F and E-E in FIG. 5A, respectively. The cross-sections F-F and E-E correspond to cross-sections B-B and C-C in FIG. 1, respectively. Note that FIG. 5A illustrates the cross-sectional view along the longitudinal direction (e.g., a current flow direction) of one of the fins 90, the cross-sectional views along the longitudinal directions (e.g., current flow directions) of other fins 90 are the same or similar unless otherwise specified. In addition, FIG. 5A illustrates two dummy gate structures 101 as a non-limiting example, the number of dummy gate structures 101 over the fins 90 may be any suitable number.

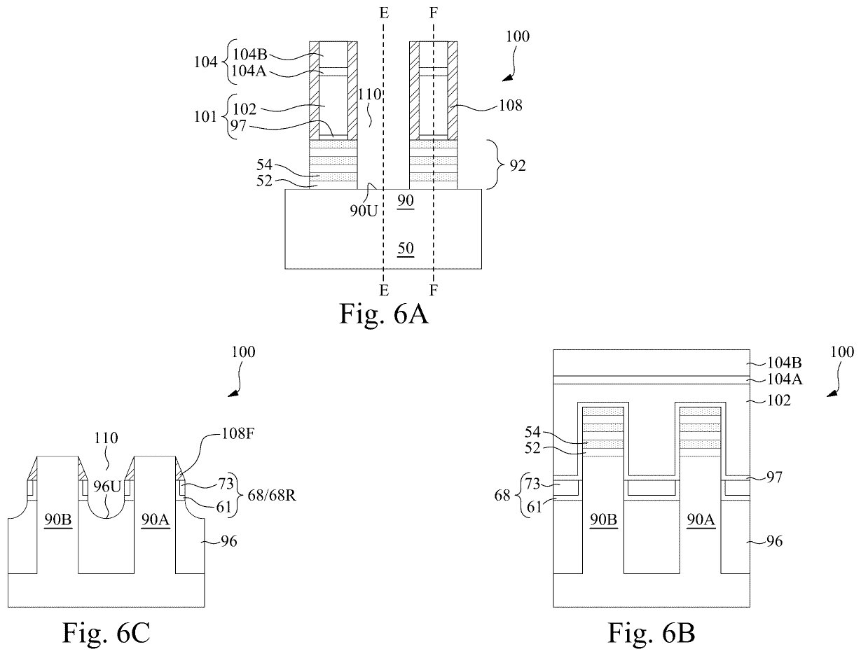

Next, in FIGS. 6A-6C, the gate spacer layers 108 are etched by an anisotropic etching process to form gate spacers 108. The anisotropic etching process may remove horizontal portions of the gate spacer layer 108 (e.g., portions over the STI protection structure 68 and the dummy gate structures 101), with remaining vertical portions of the gate spacer layer 108 along sidewalls of the dummy gate structures 101 forming the gate spacers 108. In addition, the remaining vertical portions of the gate spacer layer 108 along sidewalls of the fins 90 form fin spacers 108F (see, e.g., FIG. 6C).

After the formation of the gate spacers 108, implantation for lightly doped source/drain (LDD) regions (not shown) may be performed. Appropriate type (e.g., p-type or n-type) impurities may be implanted into the exposed layer stacks 92 and/or semiconductor fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities of from about 1E15/cm³ to about 1E16/cm³. An anneal process may be used to activate the implanted impurities.

Next, openings 110 (which may also be referred to as recesses or source/drain openings) are formed in the layer stacks 92. The openings 110 may extend through the layer stacks 92 and into the fins 90. The openings 110 may be formed by an anisotropic etching process using, e.g., the dummy gate structures 101 and the gate spacers 108 as an etching mask. Bottoms of the openings 110 expose upper surfaces 90U of the fins 90. Sidewalls of the openings 110 expose the first semiconductor material 52 and the second semiconductor material 54.

In the example of FIG. 6C, the anisotropic etching process for forming the source/drain openings 110 removes portions of the STI protection structure 68 that are disposed beyond sidewalls of the fin spacers 108F, and also removes portions of the underlying STI regions 96, thereby resulting in recesses in the STI regions 96. FIG. 6C shows curved (e.g., concave) upper surfaces 96U of the STI regions 96 due to the etching of the STI regions 96. Note that as illustrated in FIG. 6B, portions of the STI protection structure 68 and portions of the STI regions 96 that are disposed under (e.g., directly under) the dummy gate structures 101 are shielded from the anisotropic etching process, thus remain intact. In some embodiments, the anisotropic etching process for forming the source/drain openings 110 does not remove the STI regions 96 disposed between adjacent fins 90, and the upper surfaces of the STI regions 96 may not have the recesses as shown in FIG. 6C, and may remain substantially unchanged before and after the anisotropic etching process.

As illustrated in FIG. 6C, portions of the STI protection structure 68 remain under the fin spacers 108F, and are referred to as remaining portions 68R of the STI protection structure 68. The remaining portions 68R of the STI protection structure 68 protect the fins 90 from over-etching by the anisotropic etching process for forming the source/drain openings 110. Without the remaining portions 68R of the STI protection structure 68, over-etching by the anisotropic etching process may expose and/or remove portions of the fins 90 disposed below the fin spacers 108F. The un-intended removal of the portions of the fins 90 by the over-etching may cause the fins 90 to collapse, and/or may cause un-intended growth of epitaxial source/drain material from the un-intendedly exposed portions of the fins 90 during the subsequent source/drain regions formation process. The un-intended growth of epitaxial source/drain material between adjacent fins 90 may cause electrical short between the adjacent source/drain regions, thus causing device failure. The disclosed method herein, by having the remaining portions 68R of the STI protection structure 68, avoids the above over-etching related issues, thereby preventing or reducing the likelyhood of device failure and improving production yield. This illustrate an advantage of the presently disclosure.

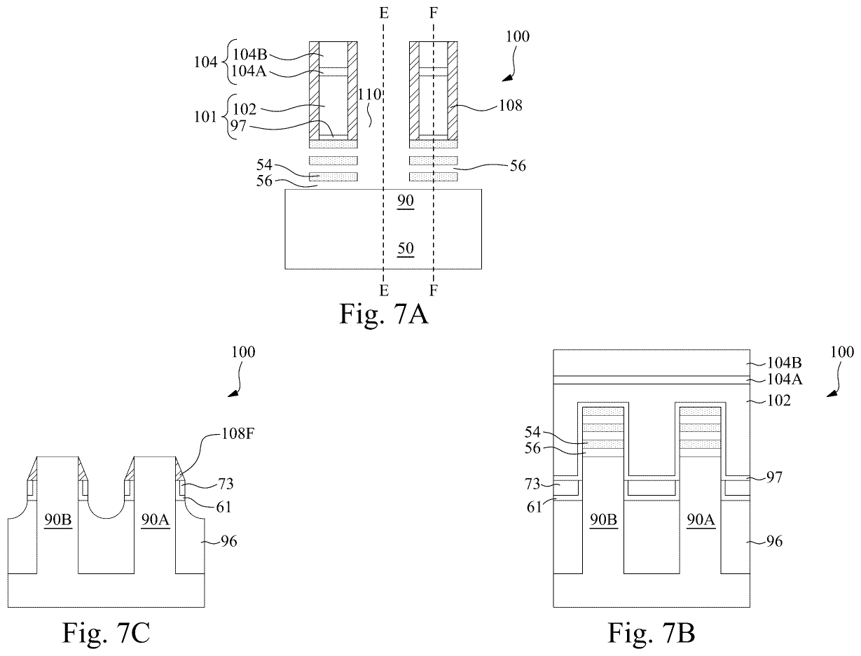

Next, in FIGS. 7A-7C, the first semiconductor material 52 under the dummy gate structures 101 and exposed by the openings 110 are removed. The first semiconductor material 52 may be removed by performing an isotropic etching process such as wet etching or the like using etchant(s) which is selective to the materials of the first semiconductor material 52, while the second semiconductor material 54, the fins 90, and the STI regions 96 remain relatively unetched as compared to the first semiconductor material 52. In embodiments in which the first semiconductor material 52 include, e.g., SiGe, and the second semiconductor material 54 include, e.g., Si or SiC, tetramethylammonium hydroxide (TMAH), ammonium hydroxide (NH₄OH), or the like may be used to selectively remove the first semiconductor material 52. After the first semiconductor material 52 is removed, gaps 56 (e.g., empty spaces) are formed between adjacent layers of the second semiconductor material 54, and between the fin 90 and a lowermost layer of the second semiconductor material 54.

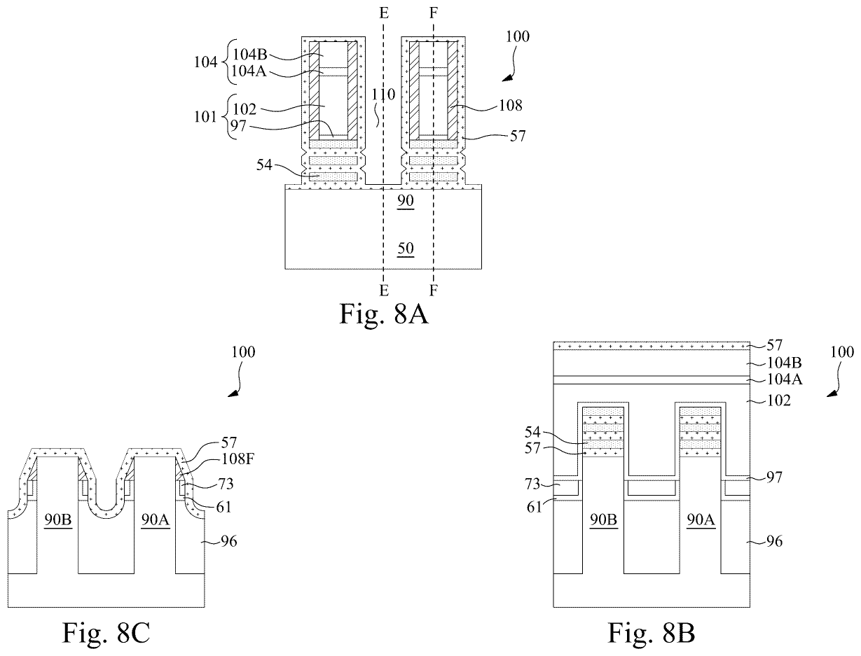

Next, in FIGS. 8A-8C, a disposable material 57 (may also be referred to as a sacrificial material) is deposited in the openings 110 to line the sidewalls and bottoms of the openings 110. The disposable material 57 also fills the gaps 56. The disposable material 57 may be deposited by a conformal deposition process, such as CVD, ALD, or the like. The disposable material 57 may be a dielectric material, such as silicon oxide (SiO), silicon oxynitride (SiON), aluminum oxide (Al₂O₃), combinations thereof, or the like. These materials are selected for their properties, such as etching selectivity, which allows for precise removal during the manufacturing process without adversely affecting the adjacent and underlying structures. The choice of the disposable material 57 may depend on the specific requirements of the semiconductor device being fabricated and the target electrical and physical properties of the final product.

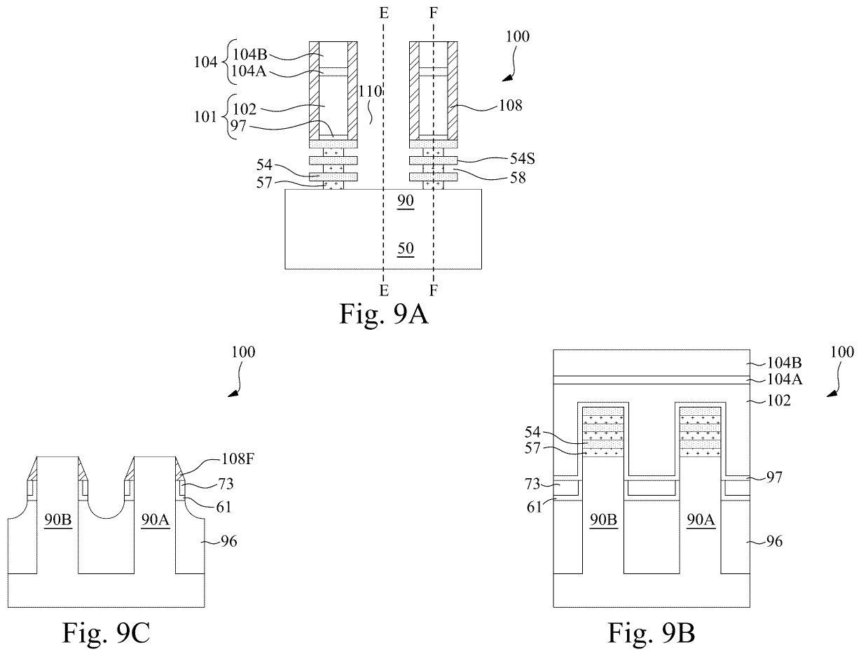

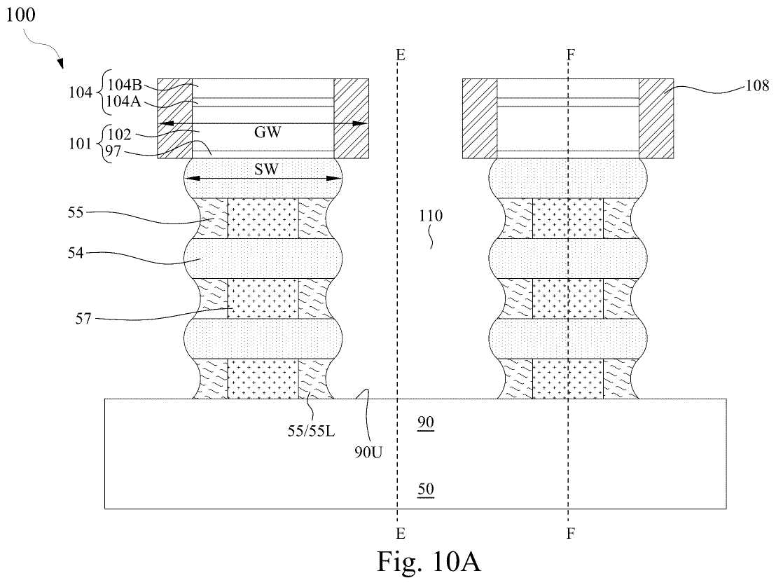

Next, in FIGS. 9A-9C, the disposable material 57 disposed outside the gaps 56 are removed, and sidewalls of the remaining portions of the disposable material 57 are recessed from respective sidewalls 54S of the second semiconductor material 54 to form sidewall recesses 58.

In some embodiments, an anisotropic etching process, e.g. a dry etching process such as a plasma etching process, is performed to remove the disposable material 57 disposed outside the gaps 56. Next, an isotropic etching process, such as a wet etching process, is performed to recess the remaining portions of the disposable material 57 to form the sidewall recesses 58. The dry etching process and the wet etching process may use etchants selective to the disposable material 57, such that the disposable material 57 is etched without substantially attacking other material(s) and/or structures. In some embodiments, multiple etching cycles, where each etching cycle includes the dry etching process followed by the wet etching process, are performed to remove the disposable material 57 and to form the sidewall recesses 58. The etching cycles are repeated until sidewalls of the disposable material 57 are recessed past sidewalls 54S of the second semiconductor material 54. In some embodiments, the disposable material 57 is etched by a wet etching process using hydrogen fluoride, diluted hydrogen fluoride, another fluorine-based etchant, or the like as an etchant. The wet etching process is performed until sidewalls of the disposable material 57 are recessed past sidewalls 54S of the second semiconductor material 54. The remaining portions of the disposable material 57, which are interposed between layers of the second semiconductor material 54, or between the fins 90 and a lowermost layer of the second semiconductor material 54, are referred to as disposable oxide interposers (DOIs). This process of replacing the first semiconductor material 52 with the DOIs may be referred to as a DOI process. In the subsequent sheet formation process, the DOIs are selectively removed to release the layers of the second semiconductor material 54 to form nanostructures 54 (e.g., nanosheets, or nanowires). The nanostructures 54 function as the channel regions of the NSFET device formed, and therefore, the second semiconductor material 54 may also be referred to as a channel material. The first semiconductor material 52 may also be referred to as a dummy material.

Replacing the first semiconductor material 52 with the disposable material 57 in the DOI process may provide advantages. To appreciate the advantages, consider a reference manufacturing process where the first semiconductor material 52 is not replaced with the disposable material 57. In subsequent source/drain formation steps, one or more high temperature processes may be performed to, for example, activate the dopants in the source/drain regions. When the first semiconductor material 52 (e.g., SiGe) is exposed to high temperatures, germanium in the first semiconductor material 52 may diffuse into and mix with the second semiconductor material 54 (e.g., Si), which is referred to as intermixing between germanium and silicon. Intermixing may increase roughness at interfaces between the first semiconductor material 52 and the second semiconductor material 54, and may cause manufacturing defects that degrade the performance of the resulting devices. By replacing the first semiconductor material 52 with the disposable material 57 prior to the high temperature processes (e.g., source/drain annealing), intermixing is avoided, and manufacturing defects can be reduced and device performance can be improved. In addition, the material (e.g., SiO) of the DOIs provide excellent etching selectivity (e.g., higher than 10,000) from the material (e.g. Si) of the second semiconductor material 54, thus allowing for selective removal of the DOIs in the sheet formation process with little or no damage to the nanostructures 54.

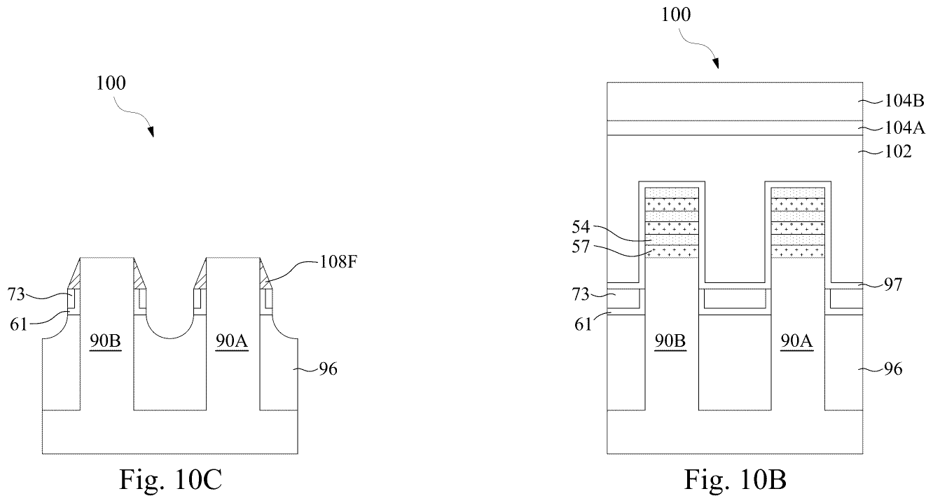

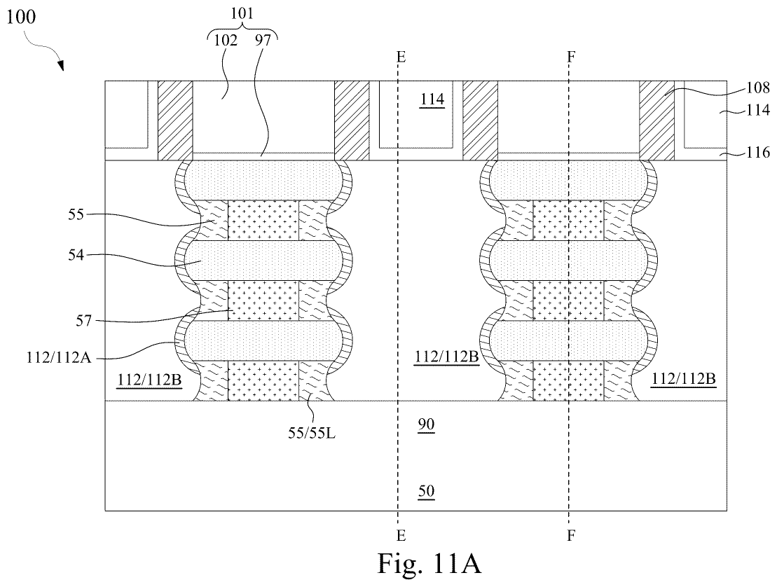

Next, in FIGS. 10A-10C, inner spacers 55 are formed in the sidewall recesses 58. In some embodiments, to form the inner spacers 55, an inner spacer layer is formed (e.g., conformally) in the openings 110 to line the sidewalls and the bottoms of the openings 110. The inner spacer layer also lines the sidewall recesses 58, and may fill the sidewall recess 58. The inner spacer layer may be a suitable dielectric material, such as silicon carbonitride (SiCN), silicon oxycarbonitride (SiOCN), or the like, formed by a suitable deposition method such as PVD, CVD, ALD, or the like. Next, an etching process(es), such as an anisotropic etching process (e.g., a plasma etching process), an isotropic etching process, combinations thereof, or the like, is performed to remove portions of the inner spacer layers disposed outside the sidewall recesses 58 of the sacrificial material 57. The remaining portions of the inner spacer layers (e.g., portions disposed inside the sidewall recesses 58 of the sacrificial material 57) form inner spacers 55. In the illustrated embodiments, the inner spacers 55 have curved sidewalls exposed to the openings 110, and are recessed from sidewalls of the second semiconductor material 54. The lateral etching rate of the etching process performed to form the inner spacers 55 may be adjusted to control how much the inner spacers 55 are recessed from the sidewalls of the second semiconductor material 54. The sidewalls of the inner spacers 55 exposed to the openings 110 may be concave (e.g., as illustrated in FIG. 10A), convex, or straight, these and other variations are fully intended to be included within the scope of the present disclosure.

In some embodiments, after the inner spacers 55 are formed, an etching process, such as an isotropic etching process, is performed using an etchant selective to the material of the second semiconductor material 54 to reduce a width SW of the second semiconductor material 54. In the illustrated embodiments, after the etching process to reduce the width SW of the second semiconductor material 54 is finished, sidewalls of the second semiconductor material 54 exposed to the openings 110 are recessed from respective exterior sidewalls of the gate spacers 108, such that the width SW is smaller than a width GW measured between opposing exterior sidewalls of the gate spacers 108. The reduced width SW of the second semiconductor material 54 allows more space for the subsequently formed epitaxial material 112C, and advantageously reduces the electrical resistance of the source/drain contacts formed. Details are discussed hereinafter.

In FIG. 10A, the sidewalls of the second semiconductor material 54 exposed to the openings 110 are illustrated as convex surfaces as a non-limiting example, with the understanding that other shapes are also possible and are fully intended to be included within the scope of the present disclosure. As illustrated in FIG. 10A, the openings 110 expose sidewalls of the second semiconductor material 54, sidewalls of the inner spacers 55, and upper surfaces 90U of the fins 90. In the example of FIG. 10A, the lowermost inner spacers 55L contact the upper surfaces 90U of the fins 90, and the uppermost layer of the second semiconductor material 54 contacts the dummy gate structures 101.

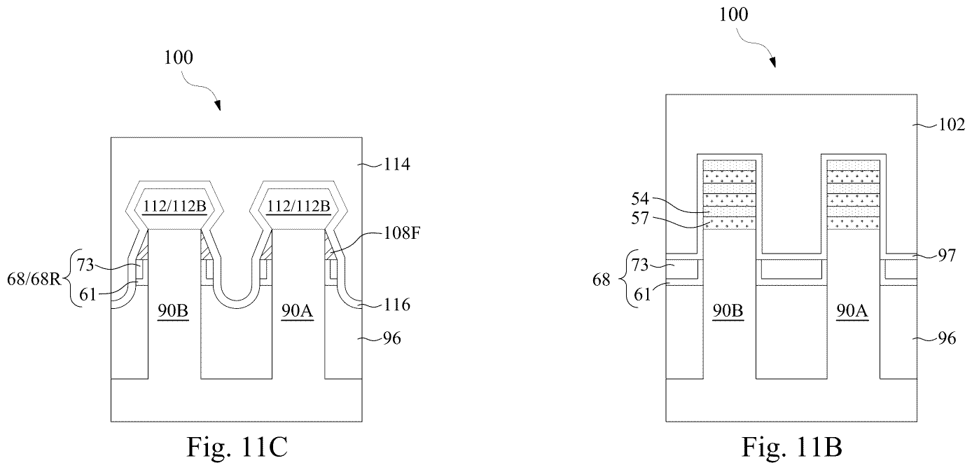

Next, as illustrated in FIGS. 11A-11C, an epitaxial material 112A and an epitaxial material 112B are formed in the source/drain openings 110. In subsequent processing, top portions of the epitaxial material 112B are replaced with an epitaxial material 112C. In the illustrated embodiments, the epitaxial material 112A, the epitaxial material 112B, and the epitaxial material 112C are collectively referred to as the source/drain regions 112 of the device formed.

In the discussion herein, source/drain region(s) may refer to a source or a drain, individually or collectively dependent upon the context. In the illustrated embodiments, the source/drain regions 112 are formed of epitaxial materials, and therefore, may also be referred to as epitaxial source/drain regions 112. In some embodiments, the epitaxial source/drain regions 112 are formed in the source/drain openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed gates of the resulting NSFET device.

In some embodiments, an epitaxial material 112A (may also be referred to as a first sublayer of the source/drain regions 112, or an Li layer) is formed (e.g., selectively formed) on the sidewalls of the second semiconductor material 54 exposed to the openings 110. In some embodiments, the epitaxial material 112A is epitaxially grown in the openings 110. The epitaxial material 112A may include any acceptable material appropriate for n-type devices. For example, the epitaxial material 112A may include material(s) exerting a tensile strain in the channel regions and may include an n-type dopant. In an example embodiment, the epitaxial material 112A is arsenic-doped silicon (Si:As). A concentration of the dopant (e.g., arsenic) in the epitaxial material 112A may be between about 5E20/cm³ and about 1E21/cm³, as an example.

The epitaxial process for forming the epitaxial material 112A is performed using a gas source that includes a silicon-containing gas, an arsenic-containing gas, and a growth-rate control gas, in some embodiments. The silicon-containing gas (may also be referred to as a silicon-containing precursor) may be, e.g., SiH₄, Si₂H₆, or SiH₂Cl₂. The arsenic-containing gas (may also be referred to as an arsenic-containing precursor) may be, e.g., AsH₃. The growth-rate control gas may be, e.g., HCl, which is used to control the growth rate of the epitaxial material 112A. The epitaxial process for forming the epitaxial material 112A may be performed at a temperature between about 500° C. and about 800° C. The epitaxial material 112A is formed along sidewalls of the openings 110, and partially fills the openings 110.

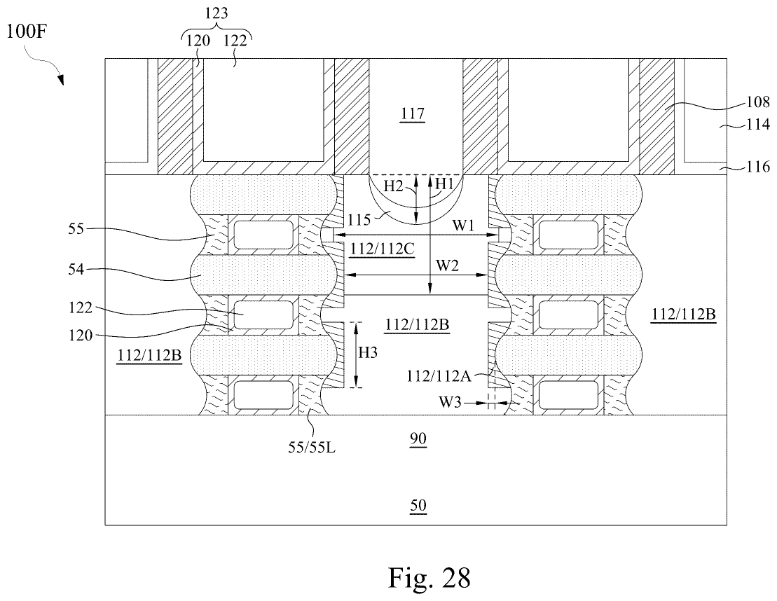

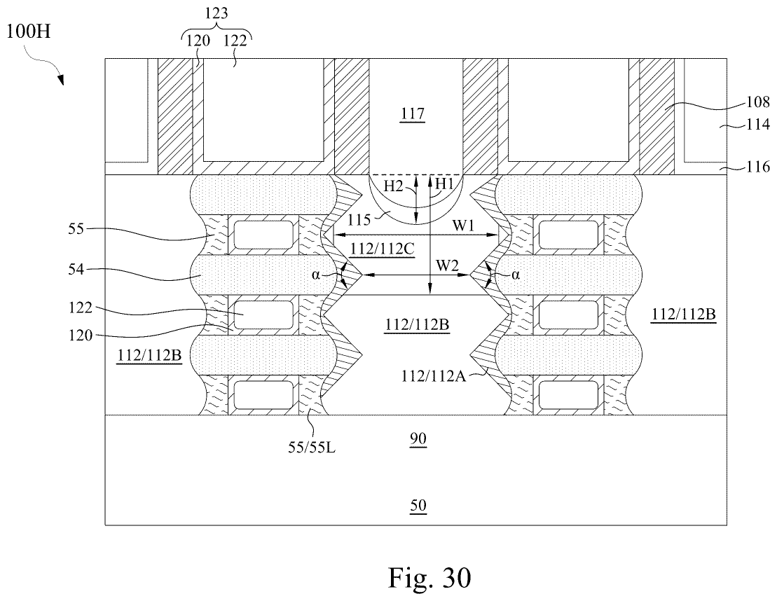

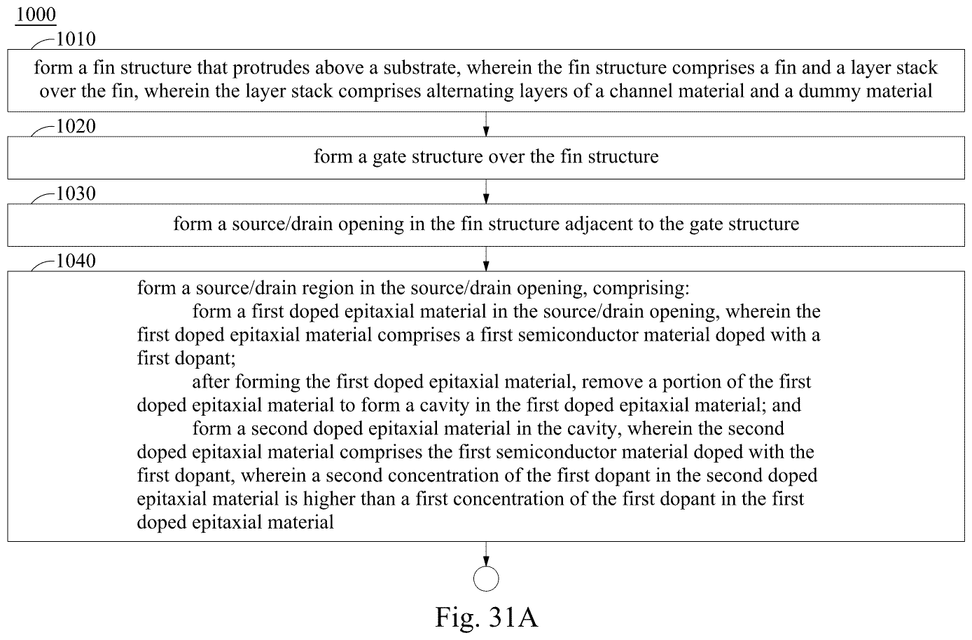

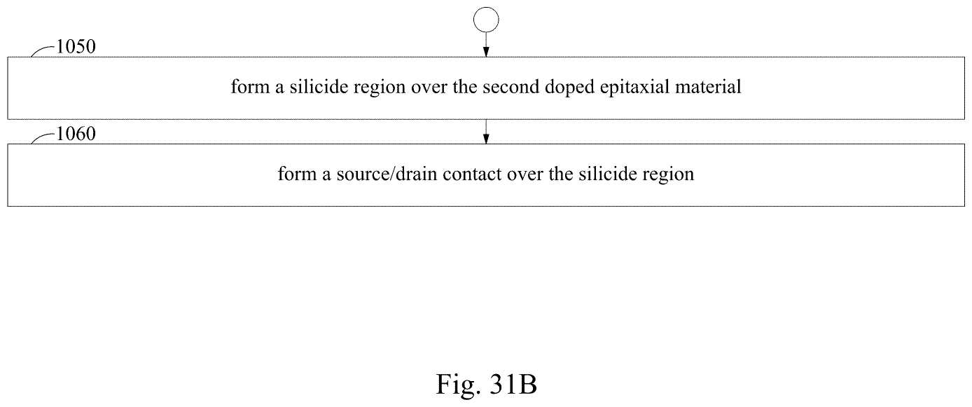

As illustrated in FIG. 11A, the epitaxial material 112A is selectively formed on the sidewalls of the second semiconductor material 54 exposed to the openings 110. In some embodiments, due to the selective growth, the epitaxial material 112A comprises discrete (e.g., separate) portions that are disposed on respective sidewalls of the second semiconductor material 54. The exterior surfaces of the epitaxial material 112A exposed to the openings 110 may have, e.g., a circular shape as illustrated in FIG. 11A, or other shapes, such as a V-shape (see, e.g., FIG. 30), or a U-shape (see, e.g., FIG. 28). In some embodiments, the epitaxial material 112A that are grown on respective sidewalls of the second semiconductor material 54 may originally include discrete portions, and depending on the condition (e.g., duration) of the epitaxy process to form the epitaxial material 112A, the sizes of the discrete portions may grow, and the original discrete portions may contact each other, as illustrated in FIG. 30.

Next, in FIGS. 11A-11C, the epitaxial material 112B (may also be referred to as a second sublayer of the source/drain regions 112, or an L2 layer) is formed on the exterior surfaces of the epitaxial material 112A exposed to the openings 110. The epitaxial material 112B includes material(s) exerting a tensile strain in the channel regions and may include an n-type dopant. In the illustrated embodiments, the epitaxial material 112B is phosphorous-doped silicon (Si:P). A concentration of the dopant (e.g., phosphorous) in the epitaxial material 112B may be between about 5E20/cm³ and about 1E21/cm³, as an example. In some embodiments, the concentration of n-type dopant in the epitaxial material 112B is higher than that in the epitaxial material 112A, e.g., by about 50% to about 300%. In some embodiments, each of the epitaxial materials 112A and 112B has a respective uniform (e.g., uniform within process variation) dopant concentration. In other embodiments, the epitaxial material 112A (or 112B) has a non-uniform dopant concentration, such as a gradient concentration where the dopant concentration changes continuously along a direction, e.g., a laterally direction, or a vertical direction. The flow rate of the gas comprising the n-type dopant may be changed (e.g., increased continuously) during the epitaxy process to achieve the gradient dopant concentration for the epitaxial material 112A (or 112B).

The epitaxial process for forming the epitaxial material 112B is performed using a gas source that includes a silicon-containing gas, a phosphorous-containing gas (may also be referred to as a phosphorous-containing precursor), and a growth-rate control gas, in some embodiments. The silicon-containing gas may be, e.g., SiH₄, Si₂H₆, or SiH₂Cl₂. The phosphorous-containing gas may be, e.g., PH₃. The growth-rate control gas may be, e.g., HCl, which is used to control the growth rate of the epitaxial material 112B. The epitaxial process for forming the epitaxial material 112B may be performed at a temperature between about 500° C. and about 800° C. The epitaxial material 112B fills the remaining portions of the openings 110, in some embodiments. For ease of discussion, the epitaxial materials 112A and 112B may be collectively referred to as the source/drain regions 112 before the epitaxial material 112C is formed to replace portions of the epitaxial material 112B. After the epitaxial material 112C is formed, the epitaxial materials 112A, 112B, and 112C are collectively referred to as the source/drain regions 112.

In the above example, the epitaxial materials 112A and 112B are in-situ doped with n-type dopants (e.g., As, P). In some embodiments, after the epitaxial materials 112A and 112B are formed, a thermal anneal process is performed, e.g., to activate the dopants. In other embodiments, each of the epitaxial materials 112A and 112B is formed by a corresponding epitaxy process similar to that described above, but without the gas comprising the n-type dopant. After the epitaxial material 112A (or 112B) is formed, the dopant (e.g., As or P) is implanted into the epitaxial material using an implantation process. A thermal anneal process is then performed after the epitaxial materials 112A and 112B are formed to activate the dopants. These and other variations are fully intended to be included within the scope of the present disclosure.

As a result of the epitaxy processes used to form the epitaxial source/drain regions 112, upper surfaces of the epitaxial source/drain regions 112 have facets which expand laterally outward beyond sidewalls of the fins 90. In some embodiments, adjacent epitaxial source/drain regions 112 over adjacent fins 90 remain separated after the epitaxy process is completed (see, e.g., FIG. 11C). In other embodiments, these facets cause adjacent epitaxial source/drain regions 112 to merge.

Still referring to FIGS. 11A-11C, next, a contact etch stop layer (CESL) 116 is formed (e.g., conformally) over the source/drain regions 112 and over the dummy gate structures 101, and a first inter-layer dielectric (ILD) 114 is then deposited over the CESL 116.

The CESL 116 is formed of a material having a different etch rate than the first ILD 114, and may be formed of silicon nitride using PECVD, although other dielectric materials such as silicon oxynitride, silicon carbide, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, PECVD, or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may also be used.

Next, a planarization process, such as a CMP process, is performed to remove the CESL 116 and the first ILD 114 from the upper surfaces of the dummy gate structures 101. The planarization process also removes the mask 104, in the illustrated embodiments. After the planarization process, the dummy gates 102, the gate spacers 108, the first ILD 114, and the CESL 116 have a coplanar upper surface.

Note that for simplicity, the source/drain regions 112 in subsequent figures may not show all the details of the source/drain regions 112, and may omit the epitaxial material 112A, with the understanding that the source/drain regions 112 include the epitaxial material 112A and other layers of epitaxial materials (e.g., 112B, 112C).

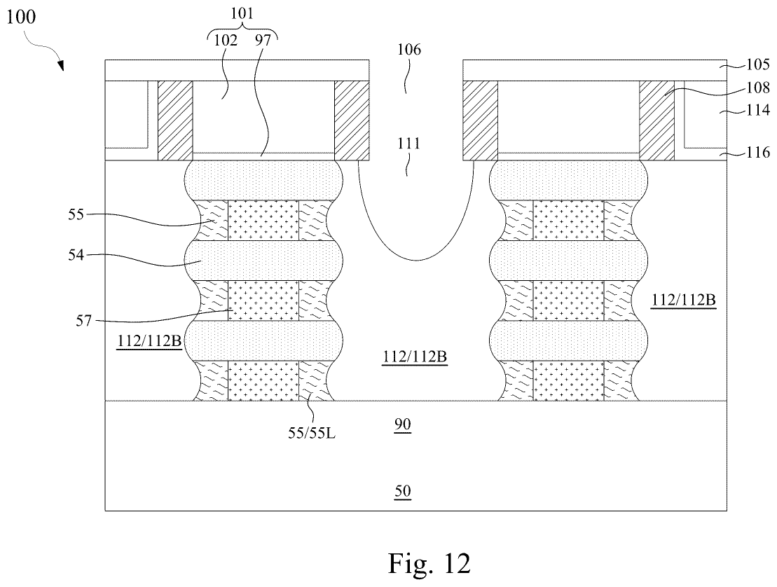

Next, in FIG. 12, a patterned mask layer 105, such as a patterned photoresist layer, is formed over the dummy gates 102, the gate spacers 108, the CESL 116, and the first ILD 114. The patterns (e.g., openings) of the patterned mask layer 105 are at locations where source/drain contacts are to be formed. Next, one or more anisotropic etching processes are performed using the patterned mask layer 105 as an etching mask, such that portions of the first ILD 114 and portions of the CESL 116 are removed to form openings 106. The openings 106 extend through the first ILD 114 and the CESL 116 to expose the underlying source/drain regions 112. In the example of FIG. 12, the openings 106 expose sidewalls of the gate spacers 108.

Next, cavities 111 are formed in the source/drain regions 112 under (e.g., directly under) respective openings 106. In some embodiments, the cavities 111 are formed by performing an etching process (e.g., a plasma etching process) using a gas source that includes Cl₂, HBr, H₂, or combinations thereof. A carrier gas, such as Ar, may be included in the gas source. In some embodiments, the gas source is ignited into plasma by a radio frequency (RF) power source for etching the source/drain regions 112. A power of the RF power source may be between about 100 W and about 1500 W. A pressure of the etching process may be between about 0.1 Torr and about 10 Torr. A temperature of the etching process may be between about 10° C. and about 200° C. A duration of the etching process may be between about 10 seconds and about 100 seconds.

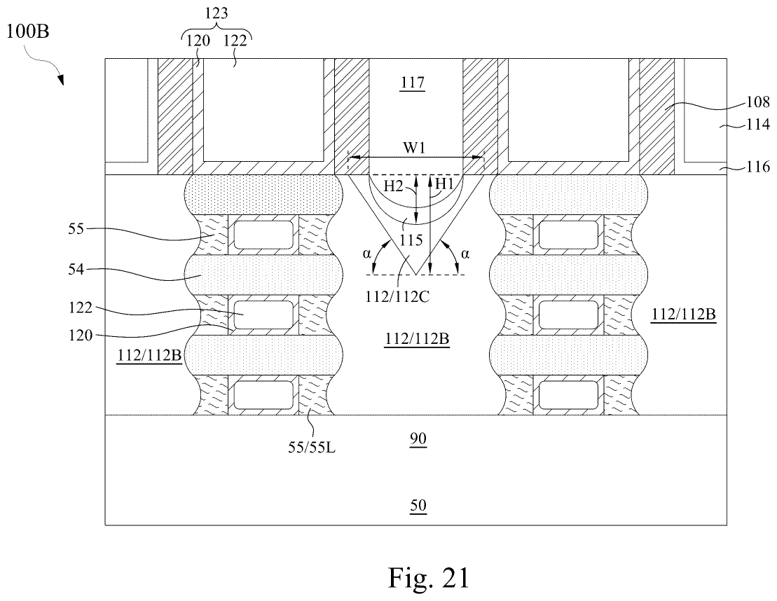

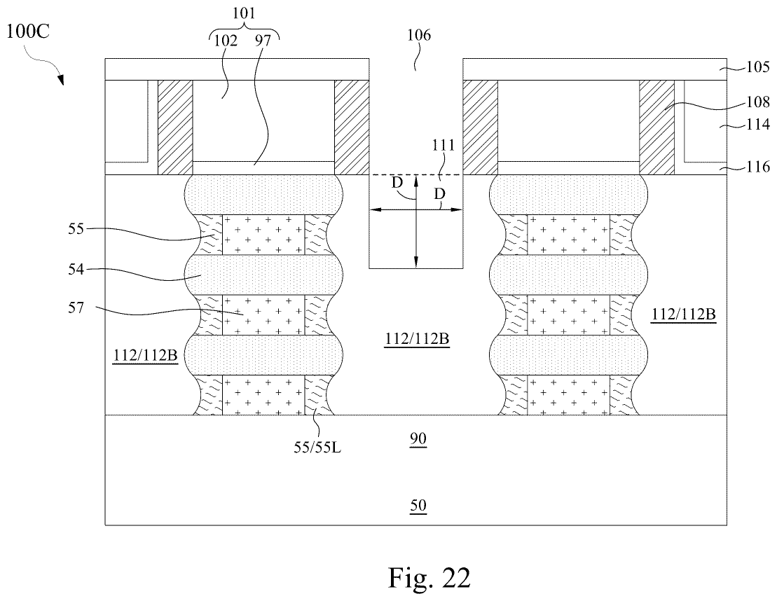

In some embodiments, the parameters of the etching process (e.g., a plasma etching process) for forming the cavities 111 are adjusted to achieve different sidewall profiles for the cavities 111. For example, a low bias and/or a low ion density of the etching process may be used to reduce the effect of ion bombardment, and to achieve a less directional but more isotropic etching, thus resulting in a curved (e.g., rounded) sidewall profile for the cavities 111, as illustrated in FIG. 12. Note that due to lateral etching of the etching process, undercuts are formed under the gate spacers 108, which allow more space for the subsequently formed epitaxial material 112C. A low bias condition may be achieved by using a low RF power, such as between about 0 W and about 100 W, for the plasma etching. A low ion density may refer to an ion density between about 1E8/cm³ and about 1E10/cm³. The ion density may be adjusted by adjusting the pressure of the plasma etching process. As another example, a high bias (e.g., RF power between about 100 W and about 1000 W) and/or a high ion density (e.g., ion density between about 1E10/cm³ and about 1E12/cm³) may be used to increase ion bombardment and to achieve anisotropic etching, thus resulting in vertical sidewalls for the cavities 111 (see, e.g., FIG. 20). As yet another example, by adjusting the etching process parameters and/or by properly choosing the etching gas(es), more chemical etching effect (e.g., chemical reactions between the ion species and the source/drain regions 112, and/or chemical reactions between etching gas(es) and the source/drain regions 112) instead of ion bombardment can be achieved, which helps to achieve a V-shaped sidewall profile for the cavities 111 (see, e.g., FIG. 21). To achieve the V-shaped sidewall profile, the RF power and/or the pressure of the plasma etching process may be between the ranges described above for the high bias/high ion density condition and the low bias/low ion density condition. In addition, a wider ion angle may be used to form the V-shaped sidewall profile for the cavities 111.

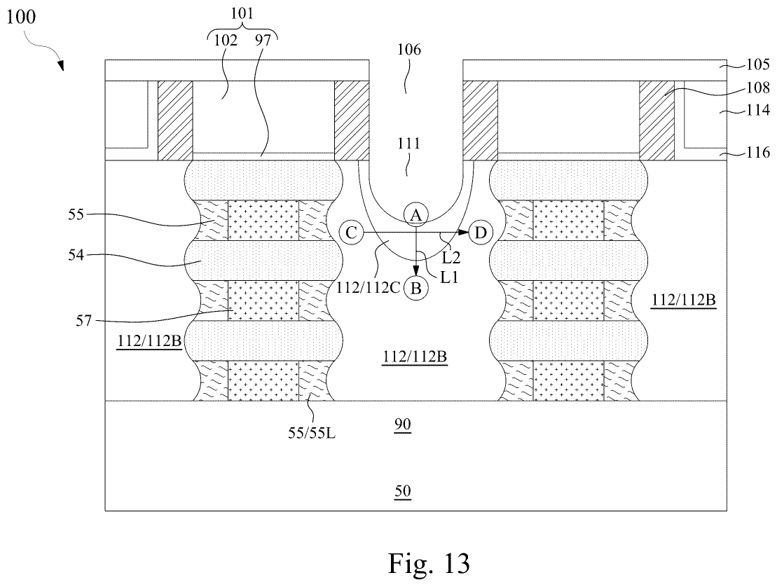

Next, in FIG. 13, an epitaxial material 112C (also referred to as a contact epitaxial material) is formed in the cavities 111 over the epitaxial material 112B. The epitaxial material 112C lines the sidewalls and bottoms of the cavities 111. In some embodiments, the epitaxial material 112C and the epitaxial material 112B comprise the same semiconductor material (e.g., Si) doped by the same dopant (e.g., P), but the epitaxial material 112C has a higher dopant concentration than the epitaxial material 112B. A concentration of the dopant (e.g., P) in the epitaxial material 112C (e.g., Si:P) may be between about 1.5E21/cm³ and about 5E21/cm³, as an example. In some embodiments, the concentration of the dopant in the epitaxial material 112C is about 50% to about 200% higher than that in the epitaxial material 112B.

In some embodiments, the epitaxial process for forming the epitaxial material 112C is performed using a gas source that includes a silicon-containing gas, a phosphorous-containing gas, and a growth-rate control gas, in some embodiments. The silicon-containing gas may be, e.g., SiH₄, Si₂H₆, or SiH₂Cl₂. The phosphorous-containing gas may be, e.g., PH₃. The growth-rate control gas may be, e.g., HCl, which is used to control the growth rate of the epitaxial material 112C. The epitaxial process for forming the epitaxial material 112C may be performed at a temperature lower than the temperature of the epitaxy process for forming the epitaxial material 112B, such as between about 300° C. and about 500° C. In some embodiments, due to the higher dopant centration of the epitaxial material 112C, no thermal anneal process is needed for the epitaxial material 112C after the epitaxy process for forming the epitaxial material 112C is finished. In contrast, a thermal anneal process may be performed after the epitaxy processes to form the epitaxial materials 112A and 112B are finished.

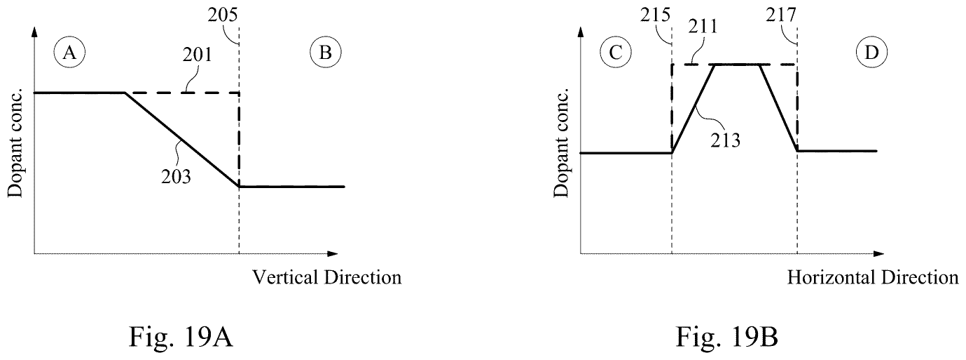

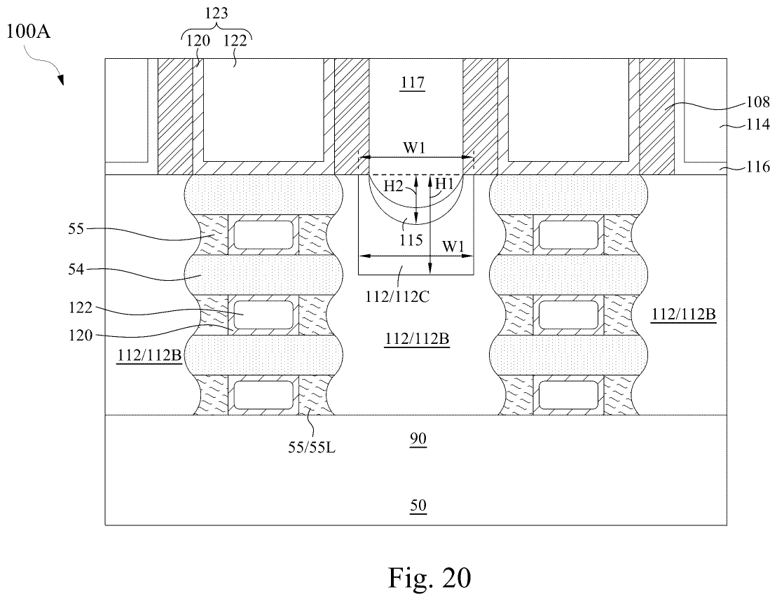

The parameters of the epitaxy process for forming the epitaxy material 112C may be adjusted to achieve different profiles for the dopant concentration in the epitaxial material 112C. FIGS. 19A and 19B illustrated examples of different dopant concentrations along the vertical direction and the horizontal direction of FIG. 13. The different dopant concentrations may be achieved by adjusting the flow rates (or ratio of flow rates) of the different gases used in the epitaxial process. Details are discussed below.

Referring temporarily to FIGS. 19A and 19B. FIG. 19A illustrates the concentration of the dopant (e.g., P) in the epitaxial material 112C along the vertical direction from location A to location B (see labels in FIG. 13), where the location A is a location at an upper surface of the epitaxial material 112C at the bottom of the cavity 111, and the location B is a location in the epitaxial material 112B under the location A. The locations A and B are illustrated in FIG. 13. The curve 201 in FIG. 19A illustrates the dopant concentration for a first scenario where the ratio between the flow rate of the phosphorous-containing gas and the flow rate of the silicon-containing gas is kept constant during the epitaxy process to form the epitaxial material 112C. The curve 203 in FIG. 19A illustrated the dopant concentration for a second scenario where the ratio between the flow rate of the phosphorous-containing gas and the flow rate of the silicon-containing gas is increased gradually to a maximum value, then kept constant at the maximum value during the epitaxy process to form the epitaxial material 112C. The dashed line 205 in FIG. 19A corresponds to the location of the interface between the epitaxial materials 112B and 112C.

The curve 201 in FIG. 19A shows that for the first scenario, the dopant concentration remains constant in the epitaxial material 112C along the vertical direction from the location A to the interface indicated by the dashed line 205, then drops to a smaller dopant concentration value that corresponds to the dopant concentration in the epitaxial material 112B. The curve 203 shows that for the second scenario, the dopant concentration in the epitaxial material 112C remains constant at a maximum value along the vertical direction for a while, before decreasing continuously to the location indicated by the dashed line 205, then dropping to a smaller dopant concentration value that corresponds to the dopant concentration in the epitaxial material 112B.

FIG. 19B illustrates the concentration of the dopant (e.g., P) in the epitaxial material 112C along the horizontal direction from location C to location D (see labels in FIG. 13), where the location C is a location in the epitaxial material 112B to the left of the epitaxial material 112C, and the location D is a location in the epitaxial material 112B to the right of the epitaxial material 112C. The locations C and D are illustrated in FIG. 13. The curves 211 and 213 in FIG. 19B illustrate the dopant concentrations for the first scenario and the second scenario discussed above, respectively. The dashed line 215 in FIG. 19B corresponds to the location of the interface between the epitaxial material 112B and a left sidewall of the epitaxial material 112C, and the dashed line 217 in FIG. 19B corresponds to the location of the interface between the epitaxial material 112B and a right sidewall of the epitaxial material 112C.

The curve 211 in FIG. 19B shows that for the first scenario, the dopant concentration remains constant in the epitaxial material 112C along the horizontal direction between the left sidewall and the right sidewall of the epitaxial material 112C. The lower dopant centration to the left of the dashed line 215 and to the right of the dashed line 217 corresponds to the dopant concentration in the epitaxial material 112B. The curve 213 shows that for the second scenario, the dopant concentration in the epitaxial material 112C increase from a lower value at the left sidewall of the epitaxial material 112C to a maximum value at a middle portion of the epitaxial material 112C, remain constant at the maximum value in the middle portion for a while, then decreases to the lower value at the right sidewall of the epitaxial material 112C. The lower value of the dopant concentration at the left sidewall and the right sidewall of the epitaxial material 112C is the same as the dopant concentration in the epitaxial material 112B.

Referring back to FIG. 13, the epitaxial material 112C lines sidewalls and bottoms of the cavities 11, and has curved upper surfaces. Due to the effect of lateral etching of the etching process performed to form the cavities 111, the cavities 111 extend under the gate spacers 108 and form undercuts. In other words, the width of each cavity 111, measured at the upper surface of the uppermost layer of the second semiconductor material 54, is wider that the width of the opening 106 over the cavity 111. As a result, the epitaxial material 112C extends under (e.g., directly under) the gate spacers 108. This increases the volume of the epitaxial material 112C, which in turn increases the volume of the subsequently formed silicide regions 115. The increased volumes of the epitaxial material 112C and the silicide regions 115 advantageously reduce the electrical resistance of the source/drain contact formed. More details are discussed hereinafter.

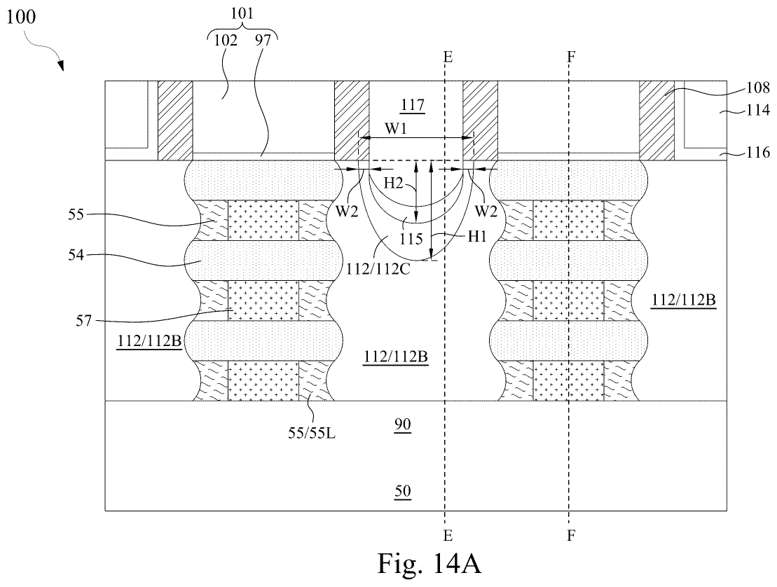

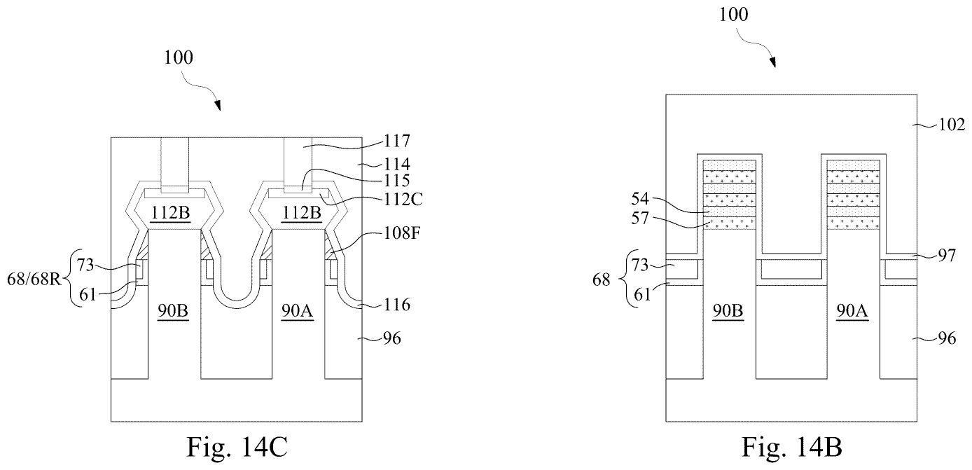

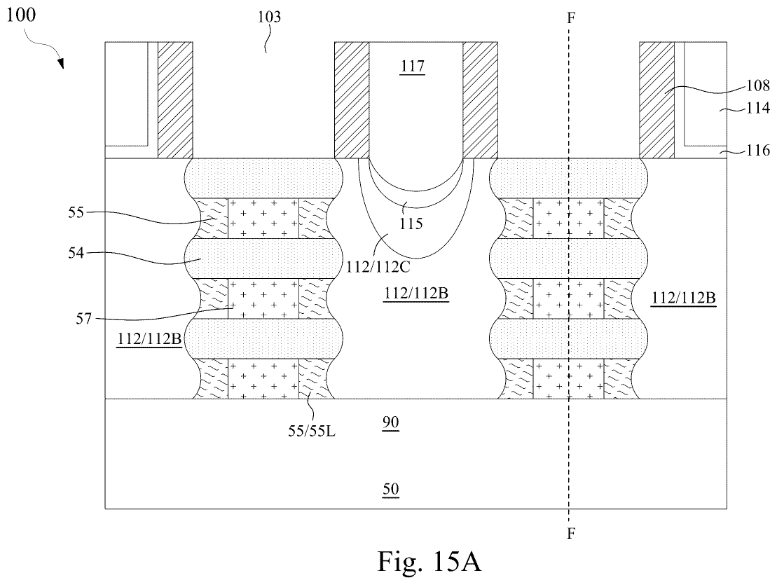

Next, in FIGS. 14A-14C, silicide regions 115 are formed in the cavities 111 on the epitaxial material 112C. In some embodiment, the silicide regions 115 are formed by first depositing a metal capable of reacting with semiconductor materials (e.g., silicon, germanium) to form silicide or germanide regions, such as nickel, cobalt, titanium, tantalum, platinum, tungsten, other noble metals, other refractory metals, rare earth metals or their alloys, over the epitaxial material 112C, then performing a thermal anneal process to form the silicide regions 115. The silicide regions 115 may have a curved profile in some embodiments. The un-reacted portions of the deposited metal are then removed, e.g., by an etching process. Although the regions 115 are referred to as silicide regions, the regions 115 may also be germanide regions, or silicon germanide regions (e.g., regions comprising silicide and germanide).

Next, source/drain contacts 117 are formed on the silicide regions 115. The source/drain contacts 117 are formed by filling the cavities 111 and the openings 106 with an electrically conductive material (e.g., copper, tungsten, cobalt, aluminum, ruthenium, combinations thereof, alloys thereof, or the like), then performing a planarization process (e.g., CMP) to remove excess portions of the electrically conductive material from the upper surface of the first ILD 114. The planarization process may also remove the patterned mask layer 105. After the planarization process, the remaining portions of the electrically conductive material in the cavities 111 and the openings 106 form the source/drain contacts 117. In some embodiments, an electrical conductivity of the silicide regions 115 is between an electrical conductivity of the epitaxial material 112C and an electrical conductivity of the source/drain contacts 117. Specifically, the electrical conductivity of the source/drain contacts 117 may be greater than the electrical conductivity of the silicide regions 115, and the electrical conductivity of the silicide regions 115 may be greater than the electrical conductivity of the epitaxial material 112C. In some embodiments, before the electrically conductive material is formed, a barrier material (not separately illustrated), such as titanium, tantalum, titanium nitride, tantalum nitride, or the like, is formed to line the sidewalls of the openings 106, using a suitable formation method such as PVD, CVD, ALD, or the like.

In the example of FIG. 14A, a width W1 of the epitaxial material 112C, measured at an upper surface of the uppermost layer of the second semiconductor material 54 between opposing exterior sidewalls of the epitaxial material 112C, is between about 10 nm and about 30 nm. A thickness W2 of the epitaxial material 112C, measured proximate to the upper surface of the uppermost layer of the second semiconductor material 54, is between about o nm and about 15 nm. A height H1 of the epitaxial material 112C, measured between the upper surface of the uppermost layer of the second semiconductor material 54 and a lowermost surface of the epitaxial material 112C, is between about 1 nm and about 40 nm. A height H2 of the silicide region 115, measured between the upper surface of the uppermost layer of the second semiconductor material 54 and a lowermost surface of the silicide region 115, is between about o nm and about 30 nm.

The structures and methods disclosed herein for forming source/drain contacts 117 provide advantages. In previous methods without the present disclosure, silicide regions of n-type devices are formed on n-type source/drain materials with low dopant concentration (e.g., the epitaxial material 112B). As a result, the electrical resistance of the source/drain contact formed is relatively high due to high Schottky barrier height and low carrier tunneling probability. The methods disclosed herein use the epitaxial material 112C with high dopant concentration to replace top portions of the epitaxial material 112B, and forms the silicide regions 115 on the epitaxial material 112C. This reduces Schottky barrier height and increases carrier tunneling probability, thereby lowering the electrical resistance of the source/drain contacts 117 formed. In addition, the volumes of the silicide regions 115 is also increased due to the shape (e.g., undercuts under the gate spacers 108) of the cavities 11 formed, which further reduces the electrical resistance.

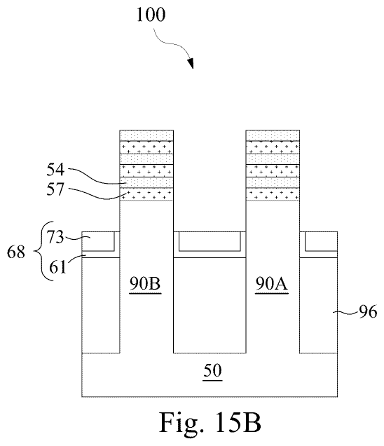

FIGS. 15A, 15B, 16A, 16B, 17A, and 17B illustrate a replacement gate process performed subsequently, where the dummy gate structures 101 are removed and replaced by replacement gate structures 123 (e.g., metal gate structures). The cross-sectional views corresponding to FIG. 14C are not illustrated for the replacement gate process, because such cross-sectional views are the same as FIG. 14C, in some embodiments.

Next, in FIGS. 15A and 15B, the dummy gates 102 are removed in an etching step(s), so that recesses 103 (may also be referred to as gate trenches) are formed between respective gate spacers 108. In some embodiments, the dummy gates 102 are removed by an anisotropic dry etching process. For example, the etching process may include a dry etching process using reaction gas(es) that selectively etch the dummy gates 102 without etching the first ILD 114 and the gate spacers 108. During the removal of the dummy gates 102, the dummy gate dielectric 97 may be used as an etch stop layer when the dummy gates 102 are etched. The dummy gate dielectric 97 may then be removed after the removal of the dummy gates 102, using, e.g., an isotropic etching process. As illustrated in FIGS. 15A and 15B, each recess 103 exposes underlying channel regions of the NSFET.

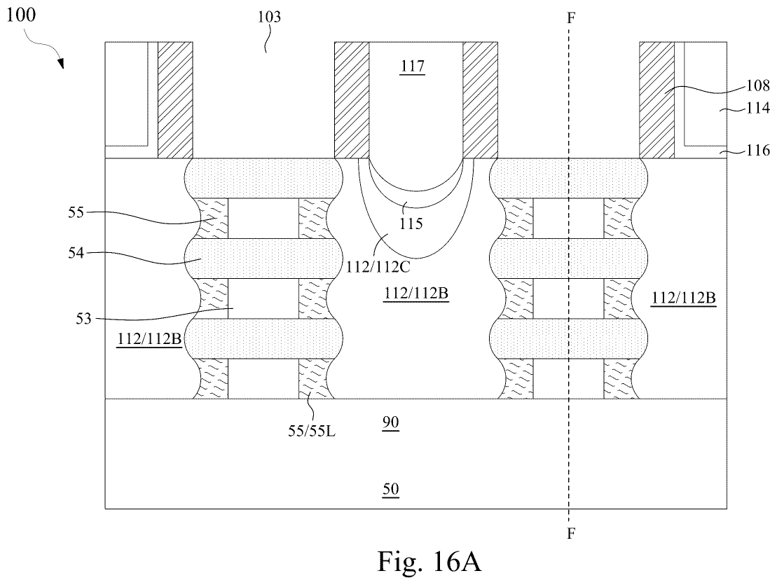

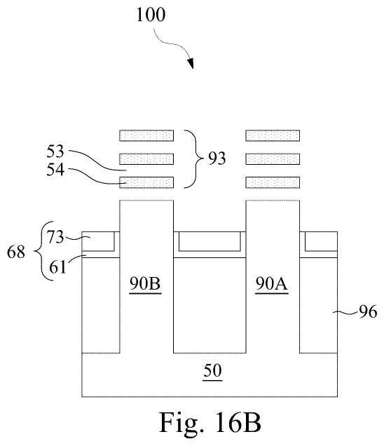

Next, in FIGS. 16A and 16B, the disposable material 57 is removed to release the second semiconductor material 54 to form nanostructure (e.g., nanosheets), and this process may be referred to as the sheet formation process. After the disposable material 57 is removed, the second semiconductor material 54 (e.g., portions underlying the dummy gate structures 101 before the dummy gate structures 101 are removed) forms a plurality of nanostructures 54 that extend horizontally (e.g., parallel to a major upper surface of the substrate 50). In some embodiments, the nanostructures 54 are nanosheets or nanowires, depending on, e.g., the dimensions (e.g., size and/or aspect ratio) of the nanostructures 54. Each nanostructure 54 may be referred to as a channel region or a channel layer of the NSFET device 100, and the nanostructures 54 may be collectively referred to as the channel regions 93 (or channel layers) of the NSFET device 100. As illustrated in FIGS. 16A and 16B, gaps 53 (e.g., empty spaces) are formed between the nanostructures 54 and between the lowermost nanostructure 54 and the fins 90 by the removal of the disposable material 57.

In some embodiments, the disposable material 57 is removed by a selective etching process using an etchant that is selective to (e.g., having a higher etch rate for) the disposable material 57, such that the disposable material 57 is removed without substantially attacking the second semiconductor material 54. In some embodiments, an isotropic etching process, such as a wet etching process or the like, is performed to remove the disposable material 57. In embodiments where the disposable material 57 include, e.g., SiO₂, and the second semiconductor material 54 include, e.g., Si or SiC, hydrogen fluoride, diluted hydrogen fluoride, another fluorine-based etchant, or the like, may be used to remove the disposable material 57.

In some embodiments, a high etching selectivity of 10,000 or more is achieved between the disposable material 57 and the second semiconductor material 54. In other words, the disposable material 57 is removed by the isotropic etching process at an etching rate 10,000 times or more than the etching rate of the second semiconductor material 54. As a result, the etching process (e.g., the sheet formation process) used to remove the disposable material 57 cause little or no damage to the nanostructures 54.

In some embodiments, both the disposable material 57 and the STI regions 96 are formed of an oxide (e.g., silicon oxide). Without the STI protection structure 68, the sheet formation process may remove upper portions of the STI regions 96 disposed under the recess 103, thus causing recessing of the STI regions 96. The recessing of the STI regions 96 reduces the distance between the subsequent formed replacement gate structure and the substrate. In addition, without the STI protection structure 68, corner regions of the STI regions 96 (e.g., regions where the upper surfaces of the STI regions 96 contact the sidewalls of the fins 90) may be removed (e.g., etched away) at a faster rate than other regions of the STI regions 96 during the sheet formation process. When the subsequently formed replacement gate structure fills the removed corner regions of the STI regions 96, protrusion of the replacement gate structure occurs. The reduced distance between the replacement gate structure and the substrate, as well as the protrusion of the replacement gate structure, cause an increase in the parasitic capacitance of the replacement gate structure. The present disclosure, by forming the STI protection structure 68, prevents or reduces the likelihood of STI region loss during the sheet formation process, thus reducing the parasitic capacitance of the NSFET device formed and improving the device performance.

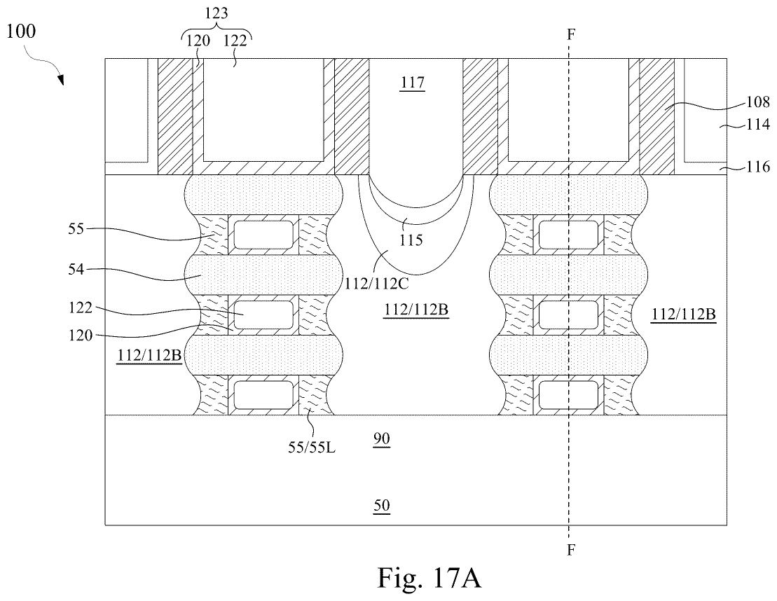

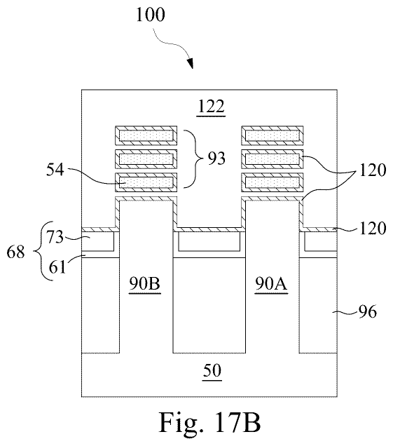

Next, in FIGS. 17A and 17B, gate dielectric layers 120 and gate electrodes 122 are formed to form replacement gate structures 123. In some embodiments, a gate dielectric material 120 is deposited conformally in the recesses 103, such as on the top surfaces and the sidewalls of the fins 90, and on sidewalls of the gate spacers 108. The gate dielectric material 120 may also be formed on the top surface of the first ILD 114. Notably, the gate dielectric material 120 is formed to wrap around the nanostructures 54. In accordance with some embodiments, the gate dielectric material 120 comprises silicon oxide, silicon nitride, or multilayers thereof. In some embodiments, the gate dielectric material 120 comprises a high-k dielectric material, and in these embodiments, the gate dielectric material 120 may have a dielectric constant (e.g., K value) greater than about 7.0, and may include a metal oxide or a silicate of Hf, Al, Zr, La, Mg, Ba, Ti, or Pb, or combinations thereof. The formation methods of the gate dielectric material 120 may include Molecular-Beam Deposition (MBD), ALD, PECVD, and the like.

Next, a gate electrode material 122 is deposited over and around the gate dielectric material 120, and fill the remaining portions of the recesses 103. The gate electrode material may include a metal-containing material such as TiN, TiO, TaN, TaC, Co, Ru, Al, W, combinations thereof, or multi-layers thereof. For example, although a single-layer gate electrode material 122 is illustrated, the gate electrode material 122 may comprise any number of liner layers (e.g., barrier layers), any number of work function tuning layers, and a fill metal material. After the filling of the gate electrode material 122, a planarization process, such as a CMP, may be performed to remove the excess portions of the gate dielectric material 120 and the gate electrode material 122, which excess portions are over the top surface of the first ILD 114. The remaining portions of the gate electrode material 122 and the gate dielectric material 120 thus form the gate electrodes 122 and the gate dielectric layers 120, respectively, of the replacement gate structures 123 of the NSFET device 100. Each gate electrode 122 and the corresponding gate dielectric layer 120 may be collectively referred to as a replacement gate structure 123, a gate structure 123, a gate stack 123, or a metal gate structure 123. Each gate structure 123 extends around the respective nanostructures 54.

Additional processing steps may be performed to complete the fabrication of the NSFET device 100, as skilled artisans readily appreciate. For example, a second ILD may be formed over the first ILD 114. Gate contacts may be formed to extend through the second ILD to be electrically coupled to the gate structures 123. Next, a front-side interconnect structure, which includes multiple dielectric layers and conductive features (e.g., vias and conductive lines) formed in the multiple dielectric layers, is formed over the second ILD to interconnect the underlying electrical components (e.g., NSFETs) to form functional circuits. Next, external connectors (e.g., copper pillars, conductive bumps) may be formed to be electrically coupled to the interconnect structure to provide electrical connection to external electrical devices. Dicing may be performed to separate multiple NSFET devices into separate individual devices. Details are not discussed here.

In some embodiments, a backside interconnect structure, which is similar to the front-side interconnect structure, is formed at the backside of the substrate 50 and is electrically coupled to conductive features of the NSFET device 100, e.g. through backside source/drain contacts and/or backside gate contacts.

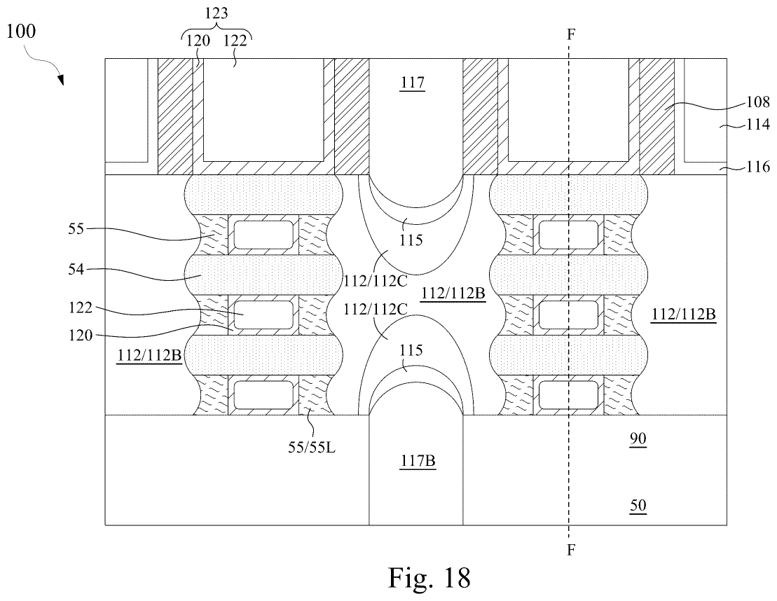

FIG. 18 illustrates an example where backside source/drain contacts 117B are formed to extend through the substrate 50 and the fin 90 to electrically couple to the source/drain regions 112. The formation process of the backside source/drain contacts 117B is same as or similar to that of the source/drain contacts 117 (may also be referred to as front-side source/drain contacts 117). For example, lower portions of the epitaxial material 112B are replaced with the epitaxial material 112C having a higher dopant concentration. Next, silicide regions 115 are formed on the epitaxial material 112C, and the openings for the backside source/drain contacts 117B are filled with an electrically conductive material. A planarization process is then performed to remove excess portions of the electrically conductive material. Details are the same as or similar to those discussed above, thus not repeated. In some embodiments, the backside interconnect structure is omitted, and no backside source/drain contacts 117B or backside gate contacts are formed.

Variations and modifications to the disclosed methods and structures are possible and are fully intended to be included within the scope of the present disclosure. For example, the source/drain contacts 117 may be formed after the replacement gate process is performed. As another example, in embodiments where backside interconnect structure is formed, the substrate 50 may be thinned or removed before the backside interconnect structure is formed.

FIG. 20 illustrates a cross-sectional view of a portion of an NSFET device 100A at a certain stage of manufacturing, in accordance with an embodiment. The NSFET device 100A is similar to the NSFET device 100 of FIG. 17A, but the epitaxial material 112C of the source/drain region 112 has straight sidewalls. As discussed above, during the etching process performed for forming the cavities 111 in the epitaxial material 112B, high bias and/or high ion density may be used to achieve high anisotropy, thereby achieving straight sidewalls for the cavities 111 due to ion bombardment. Next, the epitaxial material 112C is formed in the cavities 11, and therefore, has straight sidewalls as illustrated in FIG. 20. Next, silicide regions 115 and front-side source/drain contacts 117 are formed. Details are same as or similar to those discussed above, thus not repeated.

Although not shown, backside source/drain contact same as or similar to the front-side source/drain contacts 117 in FIG. 20 may be formed for the NSFET device 100A, as skilled artisans readily appreciate. For simplicity, backside source/drain contacts are not illustrated in subsequent figures for the various embodiments of the NSFET device, with the understanding that backside source/drain contacts having a same or similar structure as the corresponding front-side source/drain contacts may be formed.

In the example of FIG. 20, a width W1 of the epitaxial material 112C, measured between opposing exterior sidewalls of the epitaxial material 112C, is between about 10 nm and about 30 nm. A height H1 of the epitaxial material 112C, measured between the upper surface of the uppermost layer of the second semiconductor material 54 and a lowermost surface of the epitaxial material 112C, is between about 1 nm and about 40 nm. A height H2 of the silicide region 115, measured between the upper surface of the uppermost layer of the second semiconductor material 54 and a lowermost surface of the silicide region 115, is between about o nm and about 30 nm.

FIG. 21 illustrates a cross-sectional view of a portion of an NSFET device 10B at a certain stage of manufacturing, in accordance with an embodiment. The NSFET device 10B is similar to the NSFET device 100 of FIG. 17A, but the epitaxial material 112C of the source/drain region 112 has V-shaped sidewalls (e.g., triangular cross-sections). As discussed above, during the etching process performed for forming the cavities 111 in the epitaxial material 112B, by relying more on chemical etching effect instead of ion bombardment, V-shaped recesses (e.g., cavities 111) are formed in the epitaxial material 112B. For ease of discussion, the etching process to form the V-shaped recesses is also referred to as a tapered etching process. Next, the epitaxial material 112C is formed in the cavities 111, and therefore, has V-shaped sidewalls as illustrated in FIG. 21. Next, silicide regions 115 and source/drain contacts 117 are formed. Details are same as or similar to those discussed above, thus not repeated.

In the example of FIG. 21, a width W1 of the epitaxial material 112C, measured at the upper surface of the uppermost layer of the second semiconductor material 54 between opposing exterior sidewalls of the epitaxial material 112C, is between about 10 nm and about 30 nm. A height H1 of the epitaxial material 112C, measured between the upper surface of the uppermost layer of the second semiconductor material 54 and a lowermost surface of the epitaxial material 112C, is between about 1 nm and about 40 nm. A height H2 of the silicide region 115, measured between the upper surface of the uppermost layer of the second semiconductor material 54 and a lowermost surface of the silicide region 115, is between about o nm and about 35 nm. An angle α between the sidewall of the epitaxial material 112C and the horizontal direction of FIG. 21 is between about 30 degrees and about 80 degrees.

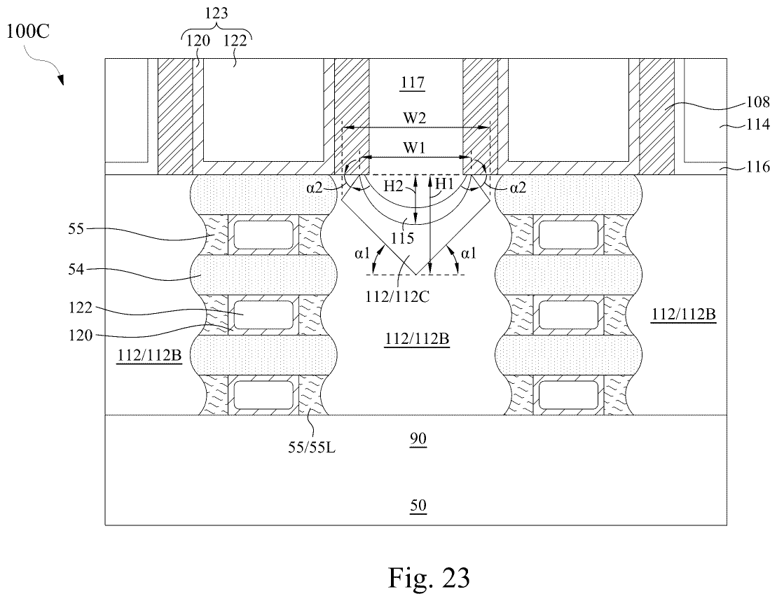

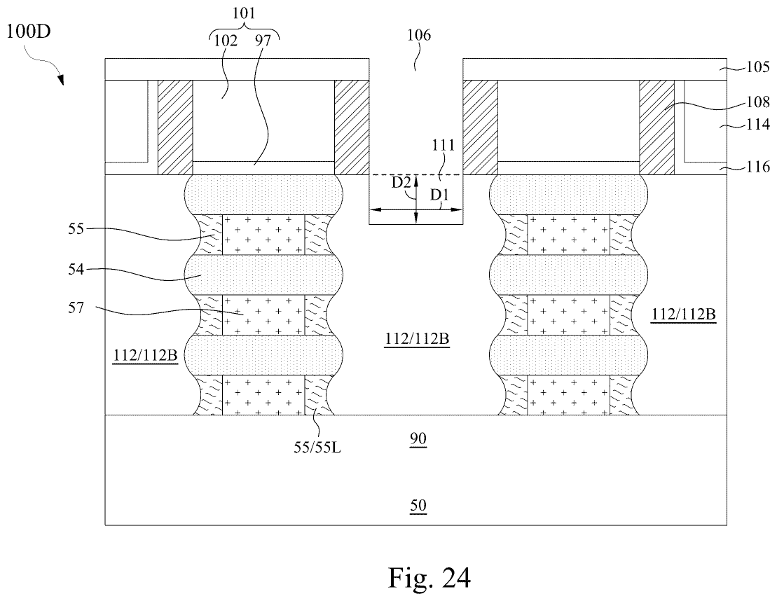

FIGS. 22 and 23 illustrate cross-sectional views of a portion of an NSFET device 100C at certain stages of manufacturing, in accordance with an embodiment. Note that while the cavities 11 for the NSFET device 100 (or 100A, or 100B) may be formed by performing a single etching process, FIGS. 22 and 23 illustrate a two-step etching process for forming the cavities 111 in the epitaxial material 112B. In particular, the two-step etching process includes a first etching step, which uses an anisotropic etching process to form cavities with straight sidewalls in the epitaxial material 112B, followed by a second etching step, which uses the tapered etching process to re-shape the cavities into user-defined target shapes. Details are discussed hereinafter.

The processing step of FIG. 22 follows the processing step of FIGS. 11A-11C. Next, as illustrated in FIG. 22, the patterned mask layer 105 is formed over the first ILD 114 and the dummy gate structures 101. Next, openings 106 are formed using the patterned mask layer 105 as an etching mask. The openings 106 are formed to extend through the first ILD 114 and the CESL 116, thereby exposing the underlying source/drain regions 112. Next, cavities 111 are formed in the epitaxial material 112B under the respective openings 106. The cavities 111 in FIG. 22 are formed by the first etching step of the two-step etching process, which is same as or similar to the anisotropic etching process performed for forming the cavities 111 in FIG. 20 with straight sidewalls. In some embodiment, the first etching step is controlled (e.g., timed) such that the cavities 111 have square-shaped cross-sections. In other words, the width and the height of the cavity 111 have the same value D, as illustrated in FIG. 22.

Next, in FIG. 23, the second etching step of the two-step etching process, which is the tapered etching process, is performed to re-shape the cavities 111 formed in the first etching step. The tapered etching process is same as or similar to the etching process performed for forming the V-shaped cavities 111 in FIG. 21. Note that in FIG. 21, each opening 106 exposes only one surface (which is the upper surface) of the epitaxial material 112B, and the chemical etching effect of the tapered etching process results in V-shaped recesses extending from the exposed surface (e.g., the upper surface) into the epitaxial material 112B. In FIG. 22, the first etching step forms cavities 111 in the epitaxial material 112B, where each cavity 111 exposes multiple surfaces of the epitaxial material 112B. In other words, the sidewalls and the bottom of each cavity 111 exposes different surfaces of the epitaxial material 112B.

When the tapered etching process is performed as the second etching step, a V-shaped recess is formed at each of the exposed surfaces of the epitaxial material 112B. For example, a V-shaped recess is formed to extend from each sidewall of the cavity 111 laterally into the epitaxial material 112B, and a V-shaped recess is formed to extend from the bottom of the cavity 111 vertically into the epitaxial material 112B. Therefore, in FIG. 23, after the second etching step, each of the re-shaped cavities 111 has a diamond-shaped cross-section formed by the V-shaped recessed at the sidewalls and the bottom of the original cavity 111 formed in the first etching step. The diamond-shaped cross-section of each re-shaped cavity 111 is illustrated by the exterior sidewalls of the subsequently formed epitaxial material 112C in the re-shaped cavity 111.

Next, as illustrated in FIG. 23, the epitaxial material 112C is formed in the re-shaped cavities 111. Next, silicide regions 115 and source/drain contacts 117 are formed. Details are same as or similar to those discussed above, thus not repeated.

In the example of FIG. 23, a width W1 of the epitaxial material 112C, measured at the upper surface of the uppermost layer of the second semiconductor material 54, is between about 10 nm and about 30 nm. A width W2 of the epitaxial material 112C, measured horizontally between the two vertices of the two horizontally extending V-shaped portions of the epitaxial material 112C, is between about 10 nm and about 40 nm. A height H1 of the epitaxial material 112C, measured between the upper surface of the uppermost layer of the second semiconductor material 54 and a lowermost surface of the epitaxial material 112C, is between about 1 nm and about 40 nm. A height H2 of the silicide region 115, measured between the upper surface of the uppermost layer of the second semiconductor material 54 and a lowermost surface of the silicide region 115, is between about o nm and about 35 nm. An angle α1 between a lower sidewall of the epitaxial material 112C and the horizontal direction of FIG. 23 is between about 30 degrees and about 80 degrees. An angle α2 between the upper sidewall of the epitaxial material 112C and the vertical direction of FIG. 23 is between about 30 degrees and about 80 degrees.

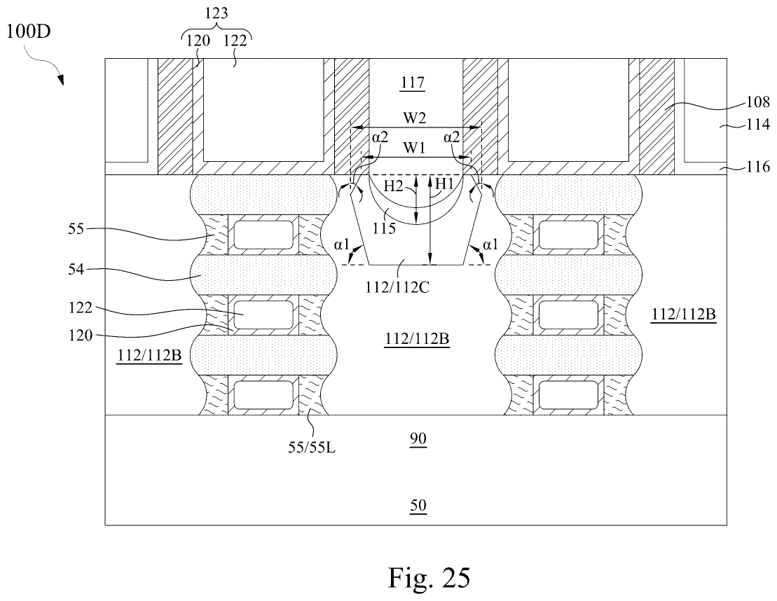

FIGS. 24 and 25 illustrate cross-sectional views of a portion of an NSFET device 100D at certain stages of manufacturing, in accordance with an embodiment. The formation process of the NSFET device 100D is similar to that of the NSFET device 100C, but in the first etching step, the cavities 111 are formed to have rectangular cross-sections, where a width D1 of the cavities 111 is larger than a depth D2 of the cavities 111, as illustrated in FIG. 24.

Next, in FIG. 25, the second etching step is performed using the tapered etching process. The second etching step may be timed, such that the V-shaped recess formed at each sidewall of the original cavity 111 in FIG. 24 is complete, meaning that the two sidewalls of the V-shaped recesses physically intersect with each other to form a V-shape in FIG. 25. Note that in the example of FIG. 25, due to the depth D2 of the cavities 111 being smaller than the width D1 of the cavities 111, the V-shaped recess formed at the bottom of each original cavity 111 in FIG. 24 is not complete, meaning that the two sidewalls of the V-shaped recess do not physically intersect with each other, and is connected by a horizontal bottom surface of the re-shaped cavity 111. As a result, the re-shaped cavities 111 have hexagon-shaped cross-sections.

Next, as illustrated in FIG. 25, the epitaxial material 112C is formed in the re-shaped cavities 111. Next, silicide regions 115 and source/drain contacts 117 are formed. Details are same as or similar to those discussed above, thus not repeated.

In the example of FIG. 25, a width W1 of the epitaxial material 112C, measured at the upper surface of the uppermost layer of the second semiconductor material 54, is between about 10 nm and about 30 nm. A width W2 of the epitaxial material 112C, measured horizontally between the two vertices of the two horizontally extending V-shaped portions of the epitaxial material 112C, is between about 10 nm and about 40 nm. A height H1 of the epitaxial material 112C, measured between the upper surface of the uppermost layer of the second semiconductor material 54 and a lowermost surface of the epitaxial material 112C, is between about 1 nm and about 40 nm. A height H2 of the silicide region 115, measured between the upper surface of the uppermost layer of the second semiconductor material 54 and a lowermost surface of the silicide region 115, is between about o nm and about 35 nm. An angle α1 between a lower sidewall of the epitaxial material 112C and the horizontal direction of FIG. 25 is between about 30 degrees and about 80 degrees. An angle α2 between the upper sidewall of the epitaxial material 112C and the vertical direction of FIG. 25 is between about 30 degrees and about 80 degrees.

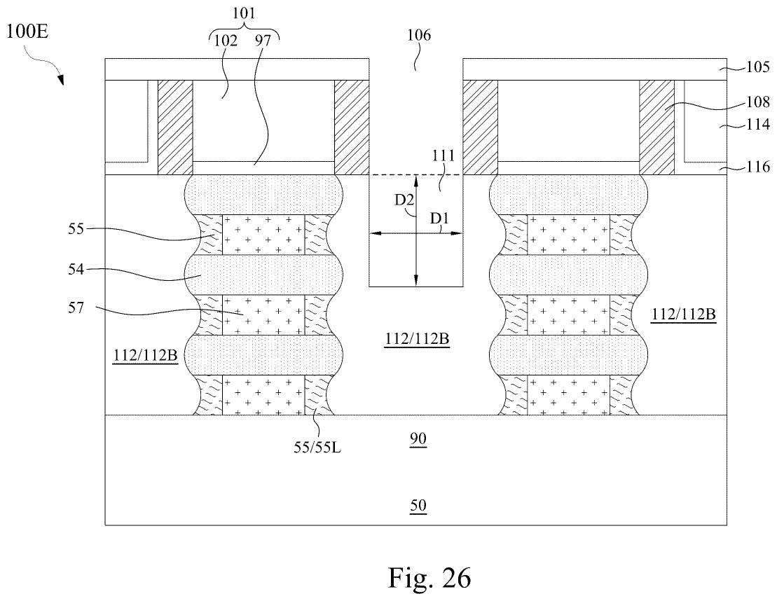

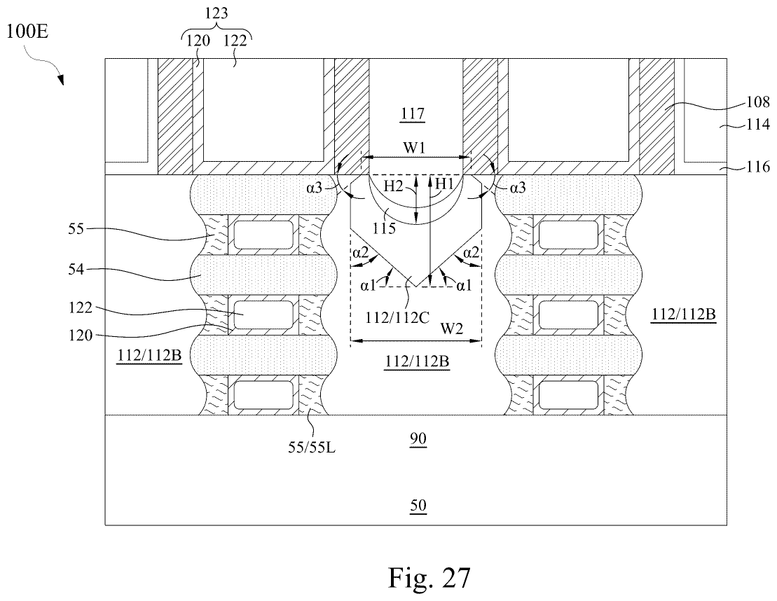

FIGS. 26 and 27 illustrate cross-sectional views of a portion of an NSFET device 100E at certain stages of manufacturing, in accordance with an embodiment. The formation process of the NSFET device 100E is similar to that of the NSFET device 100D, but in the first etching step, the cavities 11 are formed to have rectangular cross-sections, where a width D1 of the cavities 111 is smaller than a depth D2 of the cavities 11, as illustrated in FIG. 26.

Next, in FIG. 27, the second etching step is performed using the tapered etching process. The second etching step may be timed, such that the V-shaped recess formed at the bottom of the original cavity 11 in FIG. 26 is complete, meaning that the two sidewalls of the V-shaped recesses physically intersect with each other to form a V-shape in FIG. 27. Note that in the example of FIG. 27, due to the depth D2 of the cavities 11 being larger than the width D1 of the cavities 11, the V-shaped recess formed at each sidewall of each original cavity 111 in FIG. 26 is not complete, meaning that the two sidewalls of the V-shaped recess do not physically intersect with each other, and is connected by a vertical sidewall of the re-shaped cavity 111. As a result, the re-shaped cavities 111 have hexagon-shaped cross-sections. In the illustrated embodiments, there is a 90-degree rotation between the hexagon-shaped cavities 111 in FIG. 25 and the hexagon-shaped cavities 111 in FIG. 27.

Next, as illustrated in FIG. 27, the epitaxial material 112C is formed in the re-shaped cavities 111. Next, silicide regions 115 and source/drain contacts 117 are formed. Details are same as or similar to those discussed above, thus not repeated.

In the example of FIG. 27, a width W1 of the epitaxial material 112C, measured at the upper surface of the uppermost layer of the second semiconductor material 54, is between about 10 nm and about 30 nm. A width W2 of the epitaxial material 112C, measured horizontally between the two vertical sidewalls of the epitaxial material 112C, is between about 10 nm and about 40 nm. A height H1 of the epitaxial material 112C, measured between the upper surface of the uppermost layer of the second semiconductor material 54 and a lowermost surface of the epitaxial material 112C, is between about 1 nm and about 40 nm. A height H2 of the silicide region 115, measured between the upper surface of the uppermost layer of the second semiconductor material 54 and a lowermost surface of the silicide region 115, is between about o nm and about 35 nm. An angle α1 between a lower sidewall of the epitaxial material 112C and the horizontal direction of FIG. 27 is between about 30 degrees and about 8o degrees. An angle α2 between the vertical sidewall of the epitaxial material 112C and the lower sidewall of the epitaxial material 112C is between about 30 degrees and about 8o degrees. An angle α3 between the upper sidewall of the epitaxial material 112C and the horizontal direction of FIG. 27 is between about 30 degrees and about 8o degrees.

FIG. 28 illustrates a cross-sectional view of a portion of an NSFET device 100F at a certain stage of manufacturing, in accordance with an embodiment. In FIG. 28, the epitaxial material 112A of the source/drain regions 112 is illustrated. Note that for simplicity, FIG. 28 only illustrates portions of the epitaxial material 112A disposed between the two adjacent replacement gate structures 123, with the understanding that the epitaxial material 112A may also be formed along sidewalls of the nanostructures 54 at other locations.

In the example of FIG. 28, the exterior surfaces of the epitaxial material 112A along the sidewall of the nanostructure 54 are flat surfaces (e.g., comprising a horizontally extending upper surface, a horizontally extending lower surface, and vertically extending sidewall). In some embodiments, parameters of the epitaxy process for forming the epitaxial material 112A, such as the temperature and the flow rate of the growth-rate control gas (e.g., HCl), are adjusted to modify the growth rate of the epitaxial material 112A along different crystallographic planes, in order to achieve different shapes for the epitaxial material 112A. In the examples of FIGS. 28-30, the (100) crystallographic plane corresponds to the horizontal plane, the (110) crystallographic plane corresponds to the vertical plane, and the (111) crystallographic plane corresponds to a plane along a slanted direction (see, e.g., the slanted sidewall of the epitaxial material 112A in FIG. 30).

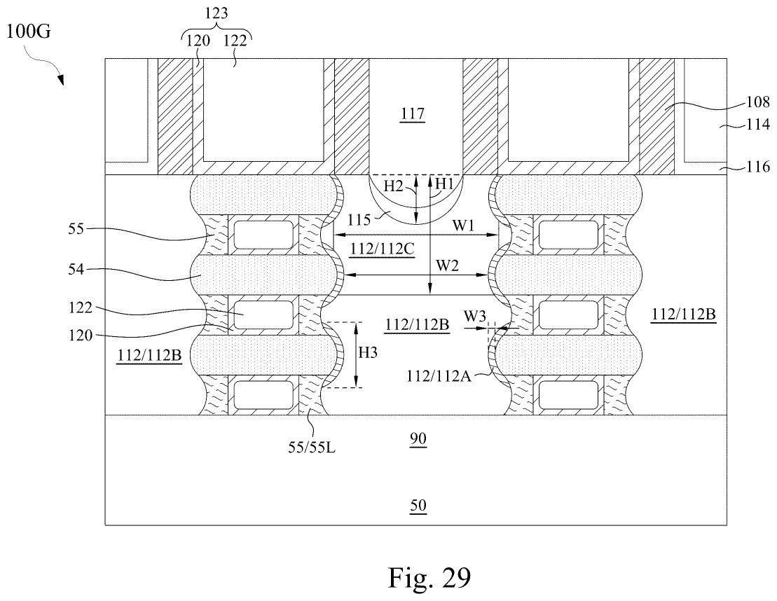

The temperature and/or the flow rate of the growth-rate control gas (e.g., HCl) can be adjusted to tune the relative growth rates of the (100), (110), and/or (111) crystallographic planes. In this manner, the different sidewall configurations of the epitaxial material 112 can be achieved. Specifically, the resulting sidewall surfaces of the epitaxial material 112a may be pinned to a facet of a crystallographic plane with the lowest growth rate. In some embodiments, to form the epitaxial material 112A with flat surfaces as illustrated in FIG. 28, the temperature and the flow rate of the growth-rate control gas (e.g., HCl) are adjusted to achieve slower growth rate along the (100) and (110) crystallographic planes than along the (111) crystallographic plane. In some embodiments, the temperature and the flow rate of the growth-rate control gas (e.g., HCl) are adjusted to achieve equal growth rates along the (100), (110), and (111) crystallographic planes, in order to form curved sidewalls for the epitaxial material 112A, as illustrated in FIG. 29. In some embodiments, the temperature and the flow rate of the growth-rate control gas (e.g., HCl) are adjusted to achieve slower growth rate along the (111) crystallographic planes than along the (100) and (110) crystallographic plane, in order to form slanted sidewalls for the epitaxial material 112A, as illustrated in FIG. 30.

In FIG. 28, after the epitaxial material 112A is formed, the epitaxial material 112B is formed to fill the source/drain openings 110. Next, the CESL 116 and the first ILD 114 are formed. Next, openings 106 are formed that extend through the first ILD 114 and CESL 116 to expose the underlying epitaxial material 112B. Next, cavities 111 are formed in the epitaxial material 112B. The etching process for forming the cavities 111 may be tuned to achieve substantially equal lateral etching rate and vertical etching rate. In the illustrated embodiments, the etchant used in the etching process is selective to the epitaxial material 112B (e.g., Si:P), and therefore, removes little to no portions of the epitaxial material 112A (e.g., Si:As). The cavities 111 are formed large enough to expose portions of the epitaxial material 112A. Next, silicide regions 115 are formed on the epitaxial material 112C, and source/drain contacts 117 are formed on the silicide regions 115. Details are the same as or similar as those discussed above, thus not repeated.

In the example of FIG. 28, a width W1 of the epitaxial material 112C, measured at a widest portion of the epitaxial material 112C, is between about 10 nm and about 40 nm. A width W2 of the epitaxial material 112C, measured horizontally between two opposing sidewalls of the epitaxial material 112A, is between about 10 nm and about 30 nm. A thickness W3 of the epitaxial material 112A, measured at a location midway between the upper surface and the lower surface of a nanostructure 54, is between about o nm and about 5 nm. A height H1 of the epitaxial material 112C, measured between the upper surface of the uppermost layer of the second semiconductor material 54 and a lowermost surface of the epitaxial material 112C, is between about 1 nm and about 40 nm. A height H2 of the silicide region 115, measured between the upper surface of the uppermost layer of the second semiconductor material 54 and a lowermost surface of the silicide region 115, is between about o nm and about 35 nm. A height H3 of the epitaxial material 112A, measured between the upper surface and the lower surface of a portion of the epitaxial material 112A along a sidewall of a nanostructure 54, is between about o nm and about 15 nm.

FIG. 29 illustrates a cross-sectional view of a portion of an NSFET device 100G at a certain stage of manufacturing, in accordance with an embodiment. The NFET device 100G is similar to the NSFET device 100F, but the epitaxial material 112A has curved sidewalls. As discussed above, the curved sidewalls of the epitaxial material 112A may be formed by controlling the growth rates along the (100), (110), and (111) crystallographic planes to be equal. Other processing steps are the same as or similar to those for the NSFET device 100F, thus details are not repeated.

In the example of FIG. 29, a width W1 of the epitaxial material 112C, measured at a widest portion of the epitaxial material 112C, is between about 10 nm and about 40 nm. A width W2 of the epitaxial material 112C, measured between two opposing sidewalls of two separate portions of the epitaxial material 112A, is between about 10 nm and about 30 nm. A thickness W3 of the epitaxial material 112A, measured at a location midway between the upper surface and the lower surface of a nanostructure 54, is between about o nm and about 5 nm. A height H1 of the epitaxial material 112C, measured between the upper surface of the uppermost layer of the second semiconductor material 54 and a lowermost surface of the epitaxial material 112C, is between about 1 nm and about 40 nm. A height H2 of the silicide region 115, measured between the upper surface of the uppermost layer of the second semiconductor material 54 and a lowermost surface of the silicide region 115, is between about o nm and about 35 nm. A height H3 of the epitaxial material 112A, measured between the upper surface and the lower surface of a portion of the epitaxial material 112A along a sidewall of a nanostructure 54, is between about o nm and about 15 nm.

FIG. 30 illustrates a cross-sectional view of a portion of an NSFET device 100H at a certain stage of manufacturing, in accordance with an embodiment. The NFET device 100H is similar to the NSFET device 100F, but the epitaxial material 112A has slanted sidewalls that form V-shapes. As discussed above, the slanted sidewalls of the epitaxial material 112A may be formed by controlling the growth rates along the (100) and (110) crystallographic planes to be slower than the grow rate along the (111) crystallographic plane. In the example of FIG. 30, the portions of the epitaxial material 112A along the sidewalls of the nanostructures 54 merge with each other, and therefore, the epitaxial material 112A extends continuously along the vertical direction of FIG. 30 from the lowermost nanostructure 54 to the uppermost nanostructure 54. Other processing steps are the same as or similar to those for the NSFET device 100F, thus details are not repeated.

In the example of FIG. 30, a width W1 of the epitaxial material 112C, measured at a widest portion of the epitaxial material 112C, is between about 10 nm and about 40 nm. A width W2 of the epitaxial material 112C, measured between two vertices of two opposing portions of the epitaxial material 112A, is between about 10 nm and about 30 nm. A height H1 of the epitaxial material 112C, measured between the upper surface of the uppermost layer of the second semiconductor material 54 and a lowermost surface of the epitaxial material 112C, is between about 1 nm and about 40 nm. A height H2 of the silicide region 115, measured between the upper surface of the uppermost layer of the second semiconductor material 54 and a lowermost surface of the silicide region 115, is between about o nm and about 35 nm. An angle α between the V-shaped sidewalls of the epitaxial material 112A, is between about 30 degrees and about 80 degrees.

Advantages are achieved by the disclosed embodiments. For example, by replacing top portions of the epitaxial material 112B with the epitaxial material 112C with higher dopant concentration, and by forming the silicide regions 115 on the epitaxial material 112C, the electrical resistance of the source/drain contact 117 is reduced due to reduced Schottky barrier height and higher carrier tunneling probability. The increased volumes of the silicide regions 115 and the epitaxial material 112C, caused by the shape of the cavities 111 (e.g., with undercuts below the gate spacers 108), further reduces the electrical resistance of the source/drain contact 117. In addition, the use of the DOI process reduces intermixing between germanium and silicon, and provides significantly higher etching selectivity between the disposable material 57 and the second semiconductor material 54. As a result, when the sacrificial material 57 is removed to form the nanostructures 54, there is little or no damage to the nanostructures 54. As another example, the disclosed STI protection structure 68 protects the STI regions 96 (e.g., portions directly under the dummy gates) during the sheet formation process, and as a result, loss of the STI region 96 is avoided or reduced, which reduces the parasitic capacitance of the replacement gate structure 123 and improves device performance. As yet another example, the remaining portions 68R of the STI protection structure 68 under the fin spacers 108F prevents or reduces the likelyhood of the fins 90 collapsing or un-intended growth/merging of source/drain material due to over-etching of the STI regions 96 caused by the etching process used to form source/drain openings.

FIGS. 31A and 31B together illustrate a flow chart of a method 1000 of forming a semiconductor device, in accordance with some embodiments. It should be understood that the embodiment method shown in FIGS. 31A and 31B is merely an example of many possible embodiment methods. One of ordinary skill in the art would recognize many variations, alternatives, and modifications. For example, various steps as illustrated in FIGS. 31A and 31B may be added, removed, replaced, rearranged, or repeated.

Referring to FIGS. 31A and 31B, at block 1010, a fin structure is formed that protrudes above a substrate, wherein the fin structure comprises a fin and a layer stack over the fin. The layer stack comprises alternating layers of a channel material and a dummy material. In block 1020, a gate structure is formed over the fin structure. In block 1030, a source/drain opening is formed in the fin structure adjacent to the gate structure. In block 1040, a source/drain region is formed in the source/drain opening. Forming the source/drain region may include form a first doped epitaxial material in the source/drain opening, wherein the first doped epitaxial material comprises a first semiconductor material doped with a first dopant; after forming the first doped epitaxial material, removing a portion of the first doped epitaxial material to form a cavity in the first doped epitaxial material; and forming a second doped epitaxial material in the cavity. The second doped epitaxial material comprises the first semiconductor material doped with the first dopant, and a second concentration of the first dopant in the second doped epitaxial material is higher than a first concentration of the first dopant in the first doped epitaxial material. At block 1050, a silicide region is formed over the second doped epitaxial material. Subsequently, at block 1060, a source/drain contact may be formed over the silicide region.

In some embodiments a method of forming a semiconductor device includes forming a fin structure that protrudes above a substrate, wherein the fin structure comprises a fin and a layer stack over the fin, wherein the layer stack comprises alternating layers of a channel material and a dummy material; forming a gate structure over the fin structure; forming a source/drain opening in the fin structure adjacent to the gate structure; forming a source/drain region in the source/drain opening, comprising: forming a first doped epitaxial material in the source/drain opening, wherein the first doped epitaxial material comprises a first semiconductor material doped with a first dopant; after forming the first doped epitaxial material, removing a portion of the first doped epitaxial material to form a cavity in the first doped epitaxial material; and forming a second doped epitaxial material in the cavity, wherein the second doped epitaxial material comprises the first semiconductor material doped with the first dopant, wherein a second concentration of the first dopant in the second doped epitaxial material is higher than a first concentration of the first dopant in the first doped epitaxial material; forming a silicide region over the second doped epitaxial material; and forming a source/drain contact over the silicide region. Optionally in some embodiments, forming the first doped epitaxial material comprises performing a first epitaxy process to fill the source/drain opening with the first doped epitaxial material, wherein the first epitaxy process is performed using a first precursor comprising the first semiconductor material and a second precursor comprising the first dopant. Optionally in some embodiments, forming the second doped epitaxial material comprises performing a second epitaxy process to form the second doped epitaxial material in the cavity, wherein the second epitaxy process is performed using the first precursor and the second precursor, wherein a ratio of a second flow rate of the second precursor over a first flow rate of the first precursor has a higher value in the second epitaxy process than the first epitaxy process. Optionally in some embodiments, the first epitaxy process is performed at a first temperature, and the second epitaxy process is performed at a second temperature, wherein the second temperature is lower than the first temperature. Optionally in some embodiments, the method further includes after forming the first doped epitaxial material and before forming the second doped epitaxial material, performing a thermal anneal process, wherein no intervening thermal anneal process is performed after forming second doped epitaxial material and before forming the silicide region. Optionally in some embodiments, the first semiconductor material is silicon, and the first dopant is an n-type dopant. Optionally in some embodiments, the second doped epitaxial material has a first sidewall facing the gate structure and has a second sidewall laterally distal from the gate structure, wherein the second concentration of the first dopant in the second doped epitaxial material is formed to: increase along a laterally direction from the first sidewall to a first location between the first sidewall and the second sidewall; remain substantially unchanged along the laterally direction from the first location to a second location between the first location and the second sidewall; and decrease along the laterally direction from the second location to the second sidewall. Optionally in some embodiments, the first doped epitaxial material has a third sidewall facing the gate structure and has a fourth sidewall laterally distal from the gate structure, wherein the first concentration of the first dopant in the first doped epitaxial material is formed to be substantially unchanged along the laterally direction from the third sidewall to the fourth sidewall. Optionally in some embodiments, the method further includes before forming the first doped epitaxial material, forming a third doped epitaxial material along sidewalls of the layers of the channel material exposed by the source/drain opening, wherein the third doped epitaxial material comprises the first epitaxial material doped with a second dopant different from the first dopant. Optionally in some embodiments, removing the portion of the first doped epitaxial material comprises performing a selective etching process using an etchant selective to the first doped epitaxial material, wherein after performing the selective etching process and before forming the second doped epitaxial material, the third doped epitaxial material is exposed to the cavity, wherein the second doped epitaxial material is formed to be in contact with the third doped epitaxial material. Optionally in some embodiments, the method further includes after forming the source/drain opening and before forming the source/drain region: replacing the dummy material under the gate structure with a sacrificial material; and replacing end portions of the sacrificial material exposed to the source/drain opening with inner spacers. Optionally in some embodiments, the method further includes replacing the gate structure with a replacement gate structure, comprising: removing the gate structure to expose the sacrificial material and the channel material; removing the exposed sacrificial material, wherein after removing the exposed sacrificial material, the channel material remains to form channel layers of the semiconductor device; and forming a gate dielectric material and a gate electrode material around the channel layers.

In some embodiments a method of forming a semiconductor device includes forming a fin structure that protrudes above a substrate, wherein the fin structure comprises a fin and a layer stack over the fin, wherein the layer stack comprises layers of a channel material interleaved with layers of a dummy material; forming a dummy gate structure over the fin structure; forming a source/drain opening in the fin structure at a first side of the dummy gate structure; forming a source/drain region in the source/drain opening, comprising: forming a first doped epitaxial material in the source/drain opening, wherein the first doped epitaxial material comprises a semiconductor material doped with a dopant; after forming the first doped epitaxial material, forming a cavity in the first doped epitaxial material; and forming a second doped epitaxial material in the cavity, wherein the second doped epitaxial material comprises the semiconductor material doped with the dopant, wherein the second doped epitaxial material has a higher concentration of the dopant than the first doped epitaxial material; forming a silicide region on the second doped epitaxial material; forming a source/drain contact on the silicide region; and replacing the dummy gate structure with a replacement gate structure. Optionally in some embodiments, the semiconductor device is an n-type semiconductor device, and the dopant is an n-type dopant. Optionally in some embodiments, forming the first doped epitaxial material comprises filling the source/drain opening with the first doped epitaxial material such that an upper surface of the first doped epitaxial material distal from the substrate extends at least at a same distance from the substrate as an upper surface of an uppermost layer of the channel material. Optionally in some embodiments, forming the cavity comprises: performing a first etching process, wherein the first etching process removes a portion of the first doped epitaxial material to form an opening in the first doped epitaxial material; and after performing the first etching process, performing a second etching process different from the first etching process to modify a shape of the opening. Optionally in some embodiments, the first doped epitaxial material is formed at a first temperature, wherein the second doped epitaxial material is formed at a second temperature lower than the first temperature.

In some embodiments, a semiconductor device includes a substrate; a fin protruding above the substrate; channel layers stacked vertically over the fin; a gate structure around the channel layers; a source/drain region over the fin adjacent to the gate structure, wherein the source/drain region comprises: a first doped epitaxial material; and a second doped epitaxial material embedded in the first doped epitaxial material, wherein the first doped epitaxial material and the second doped epitaxial material comprise a semiconductor material doped by a first dopant, wherein the second doped epitaxial material has a higher concentration of the first dopant than the first doped epitaxial material; a silicide region on the second doped epitaxial material; and a source/drain contact on the silicide region. Optionally in some embodiments, the first dopant is an n-type dopant. Optionally in some embodiments, the source/drain region further comprises a third doped epitaxial material extending along sidewalls of the channel layers, wherein the third doped epitaxial material comprise the semiconductor material doped by a second dopant different from the first dopant, wherein the first doped epitaxial material is separated from the channel layers by the third doped epitaxial material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a fin structure that protrudes above a substrate, wherein the fin structure comprises a fin and a layer stack over the fin, wherein the layer stack comprises alternating layers of a channel material and a dummy material;
forming a gate structure over the fin structure;
forming a source/drain opening in the fin structure adjacent to the gate structure;
forming a source/drain region in the source/drain opening, comprising:
forming a first doped epitaxial material in the source/drain opening, wherein the first doped epitaxial material comprises a first semiconductor material doped with a first dopant;
after forming the first doped epitaxial material, removing a portion of the first doped epitaxial material to form a cavity in the first doped epitaxial material; and
forming a second doped epitaxial material in the cavity, wherein the second doped epitaxial material comprises the first semiconductor material doped with the first dopant, wherein a second concentration of the first dopant in the second doped epitaxial material is higher than a first concentration of the first dopant in the first doped epitaxial material;
forming a silicide region over the second doped epitaxial material; and
forming a source/drain contact over the silicide region.

2. The method of claim 1, wherein forming the first doped epitaxial material comprises performing a first epitaxy process to fill the source/drain opening with the first doped epitaxial material, wherein the first epitaxy process is performed using a first precursor comprising the first semiconductor material and a second precursor comprising the first dopant.

3. The method of claim 2, wherein forming the second doped epitaxial material comprises performing a second epitaxy process to form the second doped epitaxial material in the cavity, wherein the second epitaxy process is performed using the first precursor and the second precursor, wherein a ratio of a second flow rate of the second precursor over a first flow rate of the first precursor has a higher value in the second epitaxy process than the first epitaxy process.

4. The method of claim 3, wherein the first epitaxy process is performed at a first temperature, and the second epitaxy process is performed at a second temperature, wherein the second temperature is lower than the first temperature.

5. The method of claim 4, further comprising, after forming the first doped epitaxial material and before forming the second doped epitaxial material, performing a thermal anneal process, wherein no intervening thermal anneal process is performed after forming second doped epitaxial material and before forming the silicide region.

6. The method of claim 1, wherein the first semiconductor material is silicon, and the first dopant is an n-type dopant.

7. The method of claim 1, wherein the second doped epitaxial material has a first sidewall facing the gate structure and has a second sidewall laterally distal from the gate structure, wherein the second concentration of the first dopant in the second doped epitaxial material is formed to:
increase along a laterally direction from the first sidewall to a first location between the first sidewall and the second sidewall;
remain substantially unchanged along the laterally direction from the first location to a second location between the first location and the second sidewall; and
decrease along the laterally direction from the second location to the second sidewall.

8. The method of claim 7, wherein the first doped epitaxial material has a third sidewall facing the gate structure and has a fourth sidewall laterally distal from the gate structure, wherein the first concentration of the first dopant in the first doped epitaxial material is formed to be substantially unchanged along the laterally direction from the third sidewall to the fourth sidewall.

9. The method of claim 1, further comprising, before forming the first doped epitaxial material, forming a third doped epitaxial material along sidewalls of the layers of the channel material exposed by the source/drain opening, wherein the third doped epitaxial material comprises the first epitaxial material doped with a second dopant different from the first dopant.

10. The method of claim 9, wherein removing the portion of the first doped epitaxial material comprises performing a selective etching process using an etchant selective to the first doped epitaxial material, wherein after performing the selective etching process and before forming the second doped epitaxial material, the third doped epitaxial material is exposed to the cavity, wherein the second doped epitaxial material is formed to be in contact with the third doped epitaxial material.

11. The method of claim 1, further comprising, after forming the source/drain opening and before forming the source/drain region:
replacing the dummy material under the gate structure with a sacrificial material; and
replacing end portions of the sacrificial material exposed to the source/drain opening with inner spacers.

12. The method of claim 11, further comprising replacing the gate structure with a replacement gate structure, comprising:
removing the gate structure to expose the sacrificial material and the channel material;
removing the exposed sacrificial material, wherein after removing the exposed sacrificial material, the channel material remains to form channel layers of the semiconductor device; and
forming a gate dielectric material and a gate electrode material around the channel layers.

13. A method of forming a semiconductor device, the method comprising:
forming a fin structure that protrudes above a substrate, wherein the fin structure comprises a fin and a layer stack over the fin, wherein the layer stack comprises layers of a channel material interleaved with layers of a dummy material;
forming a dummy gate structure over the fin structure;
forming a source/drain opening in the fin structure at a first side of the dummy gate structure;
forming a source/drain region in the source/drain opening, comprising:
forming a first doped epitaxial material in the source/drain opening, wherein the first doped epitaxial material comprises a semiconductor material doped with a dopant;
after forming the first doped epitaxial material, forming a cavity in the first doped epitaxial material; and
forming a second doped epitaxial material in the cavity, wherein the second doped epitaxial material comprises the semiconductor material doped with the dopant, wherein the second doped epitaxial material has a higher concentration of the dopant than the first doped epitaxial material;
forming a silicide region on the second doped epitaxial material;
forming a source/drain contact on the silicide region; and
replacing the dummy gate structure with a replacement gate structure.

14. The method of claim 13, wherein the semiconductor device is an n-type semiconductor device, and the dopant is an n-type dopant.

15. The method of claim 13, wherein forming the first doped epitaxial material comprises filling the source/drain opening with the first doped epitaxial material such that an upper surface of the first doped epitaxial material distal from the substrate extends at least at a same distance from the substrate as an upper surface of an uppermost layer of the channel material.

16. The method of claim 13, wherein forming the cavity comprises:
performing a first etching process, wherein the first etching process removes a portion of the first doped epitaxial material to form an opening in the first doped epitaxial material; and
after performing the first etching process, performing a second etching process different from the first etching process to modify a shape of the opening.

17. The method of claim 13, wherein the first doped epitaxial material is formed at a first temperature, wherein the second doped epitaxial material is formed at a second temperature lower than the first temperature.

18. A semiconductor device comprising:
a substrate;
a fin protruding above the substrate;
channel layers stacked vertically over the fin;
a gate structure around the channel layers;
a source/drain region over the fin adjacent to the gate structure, wherein the source/drain region comprises:
a first doped epitaxial material; and
a second doped epitaxial material embedded in the first doped epitaxial material, wherein the first doped epitaxial material and the second doped epitaxial material comprise a semiconductor material doped by a first dopant, wherein the second doped epitaxial material has a higher concentration of the first dopant than the first doped epitaxial material;
a silicide region on the second doped epitaxial material; and
a source/drain contact on the silicide region.

19. The semiconductor device of claim 18, wherein the first dopant is an n-type dopant.

20. The semiconductor device of claim 19, wherein the source/drain region further comprises a third doped epitaxial material extending along sidewalls of the channel layers, wherein the third doped epitaxial material comprise the semiconductor material doped by a second dopant different from the first dopant, wherein the first doped epitaxial material is separated from the channel layers by the third doped epitaxial material.
